(19) United States
(12) Patent Application Publication
(10) Pub. No.: US 2025/0070658 A1
(43) Pub. Date: Feb. 27, 2025

(54) CHARGE PUMP CIRCUITS WITH BACKSIDE FLY CAPACITORS AND METHODS OF MANUFACTURING THEREOF

(71) Applicant: Taiwan Semiconductor Manufacturing Company, Ltd., Hsinchu (TW)

(72) Inventors: Yu-Wei Lin, Hsinchu City (TW); Meng-Sheng Chang, Hsinchu City (TW)

(73) Assignee: Taiwan Semiconductor Manufacturing Company, Ltd., Hsinchu (TW)

(21) Appl. No.: 18/523,531

(22) Filed: Nov. 29, 2023

Related U.S. Application Data
(60) Provisional application No. 63/520,831, filed on Aug. 21, 2023.

(51) Int. Cl. H02M 3/07

(52) U.S. Cl. CPC H02M 3/07

(57) ABSTRACT

A semiconductor device includes a first switch, a second switch, a third switch, and a fourth switch formed on a first side of a substrate, wherein the first switch and the second switch are connected in series between a first reference voltage and an output voltage, and wherein the third switch and the fourth switch are connected in series between the first reference voltage and a second reference voltage. The semiconductor device includes a capacitor formed on a second side of the substrate opposite to the first side, and having a first terminal and a second terminal. The first terminal is coupled to a first node between the first and second switches, and the second terminal is coupled to a second node between the third and fourth switches.

### CROSS-REFERENCE TO RELATED APPLICATION

This application claims priority to and the benefit of U.S. Provisional Application No. 63/520,831, filed Aug. 21, 2023, entitled “A NOVEL CHARGE PUMP WITH SPR PROCESS,” which is incorporated herein by reference in its entirety for all purposes.

### BACKGROUND

The semiconductor integrated circuit (IC) industry has experienced exponential growth. As ICs continue to scale down, more and more devices are integrated into the single chip. This scaling down process generally provides benefits by increasing production efficiency and lowering associated costs.

### BRIEF DESCRIPTION OF THE DRAWINGS

Aspects of the present disclosure are best understood from the following detailed description when read with the accompanying figures. It is noted that, in accordance with the standard practice in the industry, various features are not drawn to scale. In fact, the dimensions of the various features may be arbitrarily increased or reduced for clarity of discussion.

FIG. 1 illustrates a block diagram of an example memory device including a charge pump circuit, in accordance with some embodiments.

FIG. 2 illustrates an example schematic diagram of a charge pump circuit that can be included in the memory device of FIG. 1, in accordance with some embodiments.

FIG. 3 illustrates an example layout configured to form the charge pump circuit of FIG. 2, in accordance with some embodiments.

FIGS. 4 and 5 respectively illustrate cross-sectional views of a semiconductor device formed based on the layout of FIG. 3, in accordance with some embodiments.

FIGS. 6 and 7 respectively illustrate cross-sectional views of another semiconductor device formed based on the layout of FIG. 3, in accordance with some embodiments.

FIGS. 8 and 9 respectively illustrate cross-sectional views of yet another semiconductor device formed based on the layout of FIG. 3, in accordance with some embodiments.

FIGS. 10 and 11 respectively illustrate cross-sectional views of yet another semiconductor device formed based on the layout of FIG. 3, in accordance with some embodiments.

FIGS. 12 and 13 respectively illustrate cross-sectional views of yet another semiconductor device formed based on the layout of FIG. 3, in accordance with some embodiments.

FIG. 14 illustrates another example layout configured to form the charge pump circuit of FIG. 2, in accordance with some embodiments.

FIGS. 15 and 16 respectively illustrate cross-sectional views of a semiconductor device formed based on the layout of FIG. 14, in accordance with some embodiments.

FIG. 17 illustrates another example schematic diagram of a charge pump circuit that can be included in the memory device of FIG. 1, in accordance with some embodiments.

FIG. 18 illustrates an example layout configured to form the charge pump circuit of FIG. 17, in accordance with some embodiments.

FIGS. 19 and 20 respectively illustrate cross-sectional views of a semiconductor device formed based on the layout of FIG. 18, in accordance with some embodiments.

FIG. 21 illustrates a cross-sectional view of another semiconductor device formed based on the layout of FIG. 18, in accordance with some embodiments.

FIG. 22 illustrates a flow chart of an example method for fabricating a charge pump circuit that has a fly capacitor formed on the backside of a substrate, in accordance with some embodiments.

### DETAILED DESCRIPTION

The following disclosure provides many different embodiments, or examples, for implementing different features of the provided subject matter. Specific examples of components and arrangements are described below to simplify the present disclosure. These are, of course, merely examples and are not intended to be limiting. For example, the formation of a first feature over, or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “beneath,” “below,” “lower,” “above,” “upper” “top,” “bottom” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

In accordance with the scaling down of technology nodes, semiconductor memory devices are becoming more highly integrated and low operating supply voltages are being widely used. However, even memory devices that operate at a low voltage may sometimes need high voltage power supply for certain internal circuits and operations such as driving bit lines and word lines. For such a purpose, a variety of voltage provision circuits for generating high voltage (e.g., a voltage or charge pump circuit) have been developed. In general, a charge pump circuit consists of capacitors and switches. Through controlling on/off of those switches and respective timings to alternately charge and discharge the capacitors, the charge pump circuit can multiply a supply voltage to boost or pump an output voltage to a relatively high level. In addition to the memory devices (or systems), the charge pump circuit has a wide range of applications such as, for example, liquid-crystal display (LCD) drivers, micro electro-mechanical systems (MEMS), power-supply generation, etc.

In the existing technologies, the charge pump circuit typically has its switches and the capacitors formed on the same side of a substrate. However, as the technology nodes keep scaling down, the relatively high percentage of area that the capacitors occupy becomes an issue. For example, to effectively provide a sufficiently high boosted voltage, the capacitors are typically required to occupy a certain area that may disadvantageously squeeze the area available to form other device features. With the shrinking technology nodes, such a trade-off between the performance of a charge pump circuit and its occupying area becomes more critical. Thus, the existing charge pump circuit has not been entirely satisfactory in certain aspects.

The present disclosure provides various embodiments of a charge pump circuit that includes a number of switches and at least one capacitor, in which the switches and the at least one capacitor are formed on respectively different sides of a semiconductor substrate. For example, the switches, which may each be implemented as a clock-controlled field-effect transistor, may be formed along the major (e.g., frontside) surface of a substrate with a number of frontside metallization layers disposed thereupon, while the capacitor may be formed across one or more backside metallization layers disposed on a backside of the substrate. With the capacitor formed on the backside, a substantial area on the frontside can become available, which may advantageously allow more device features formed on the frontside. Further, the capacitor can be formed directly beneath the switches. As such, a total area of the disclosed charge pump circuit can be significantly reduced. Still further, as the capacitor can be formed by a number of backside interconnect structures (e.g., metal tracks), which generally present a lower resistance than frontside interconnect structures. Accordingly, parasitic resistance of the capacitor associated with the disclosed charge pump circuit can be greatly reduced. Consequently, the amount of ripple present on an output voltage (e.g., a boosted voltage) of the disclosed charge pump circuit can be advantageously reduced.

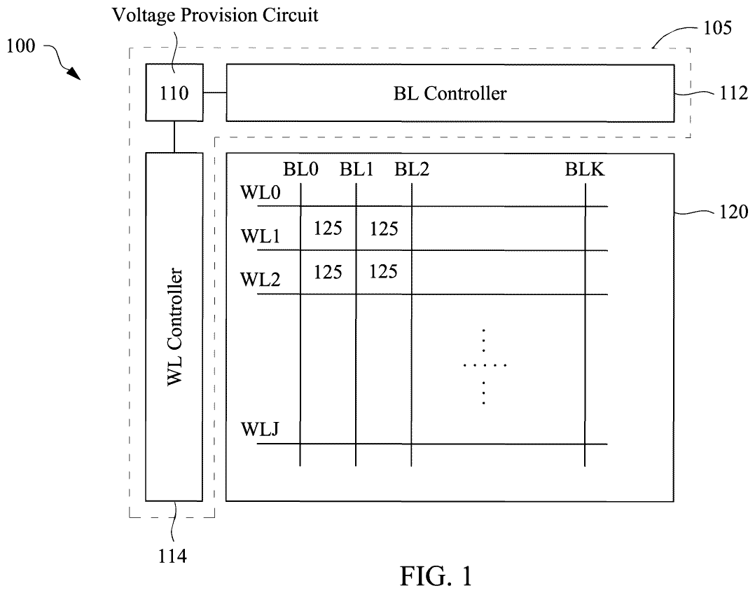

FIG. 1 illustrates a diagram of a memory device 100 including a memory controller 105 and a memory array 120, in accordance with various embodiments. In one aspect, the memory array 120 includes a plurality of storage circuits or memory cells 125. The memory array 120 further includes word lines WL₀, WL₁ . . . WL_{J}, each extending in a first direction (e.g., X-direction) and bit lines BL₀, BL₁ . . . BL_{K}, each extending in a second direction (e.g., Y-direction). The word lines WLs and the bit lines BLs may each be a conductive metal or conductive rail. In some embodiments, each memory cell 125 is coupled to a corresponding word line WL and a corresponding bit line BL, and can be operated according to voltages or currents through the corresponding word line WL and the corresponding bit line BL. In some embodiments, each bit line includes bit lines BL, BLB coupled to one or more memory cells 125 of a group of memory cells 125 disposed along the second direction (e.g., Y-direction). The bit lines BL, BLB may receive and/or provide differential signals.

Each memory cell 125 may include a volatile memory cell, a non-volatile memory cell, or a combination of them. For example, each memory cell 125 is embodied as a static random access memory (SRAM) cell. However, it should be appreciated that the memory cell 125 can be implemented as any of various other non-volatile memory cells such as, for example, a resistive random access memory (RRAM) cell, a magnetoresistive random access memory (MRAM) cell, a phase-change random access memory (PCRAM) cell, an eFuse, an anti-fuse, etc., while remaining within the scope of the present disclosure. In some embodiments, the memory array 120 includes additional lines (e.g., select lines, reference lines, reference control lines, power rails, etc.).

The memory controller 105 is a hardware component that controls operations of the memory array 120. In some embodiments, the memory controller 105 includes a bit line (BL) controller 112, a word line (WL) controller 114, and a voltage provision circuit 110. The BL controller 112, the WL controller 114, and the voltage provision circuit 110 may be embodied as logic circuits, analog circuits, or a combination of them. In one configuration, the WL controller 114 is a circuit that provides a voltage or current through one or more word lines WLs of the memory array 120, and the BL controller 112 is a circuit that provides or senses a voltage or current through one or more bit lines BLs of the memory array 120. In one configuration, the voltage provision circuit 110 is a circuit that provides a voltage signal to the BL controller 112 and/or the WL controller 114. The BL controller 112 may be coupled to bit lines BLs of the memory array 120, and the WL controller 114 may be coupled to word lines WLs of the memory array 120. In some embodiments, the memory controller 105 includes more, fewer, or different components than shown in FIG. 1.

In various embodiments, the voltage provision circuit 110 may include one or more charge pump circuits, each of which is configured to generate a boosted voltage signal to the BL controller 112 and/or the WL controller 114 for desired read/write performance. For example, to write data at a memory cell 125, the voltage provision circuit 110 can provide a boosted write voltage (or bias) to the WL controller 114, causing the boosted write voltage to be sent to the memory cell 125 through a corresponding word line WL. This allows a bit line and/or complementary bit line of the memory cell 125 to discharge faster. Therefore, the required VCCₘᵢₙ (minimum operating voltage) of the memory cell 125 (and the memory array 120 as a whole) at a particular write speed can be lowered when the voltage on the word line is boosted. In another example, during a read operation of the memory cell 125, the voltage on the word line can be boosted to more than the VCCₘᵢₙ, which allows the voltage present on the bit line to discharge faster. Accordingly, a read speed of the memory cell 125 (and the memory array 120 as a whole) can be increased.

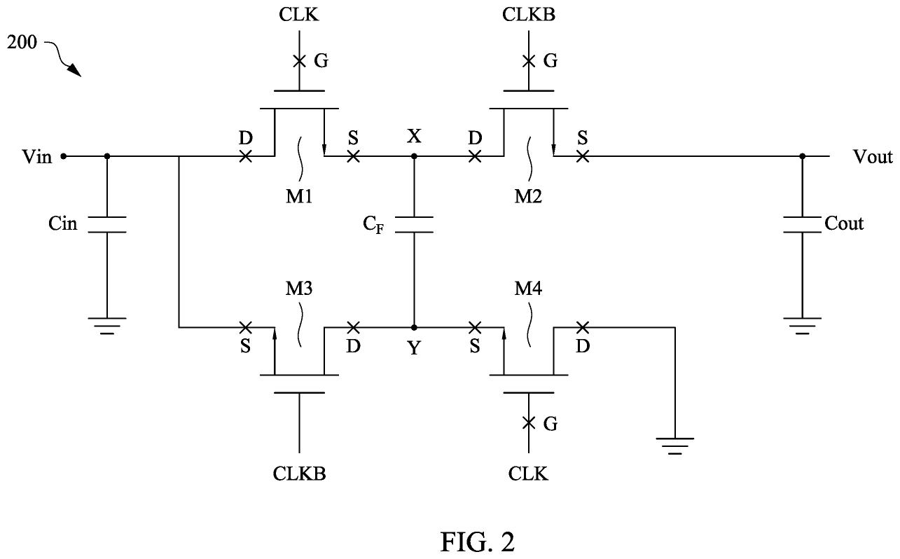

FIG. 2 illustrates an example schematic diagram 200 of the charge pump circuit of the voltage provision circuit 110 (FIG. 1), in accordance with various embodiments. Hereinafter, the charge pump circuit shown in FIG. 2 is referred to as charge pump circuit 200. It should be appreciated that the schematic diagram 200 of FIG. 2 is simplified for illustrative purposes, and thus, the charge pump circuit of the voltage provision circuit 110 can be implemented as any of various other configurations (as long as it can boost an input voltage to a higher voltage level through a capacitor) while remaining within the scope of the present disclosure.

As shown, the charge pump circuit 200 includes transistors M₁, M₂, M₃, and M₄, and at least one charge transfer capacitor (sometimes referred to as a fly capacitor) C_{F}. In the illustrative example of FIG. 2, the transistors M₁ to M₄ are each implemented as an n-type field-effect transistor. However, it should be understood that the transistors M₁ to M₄ can be implemented as other type of transistor while remaining within the scope of the present disclosure. Specifically, the transistors M₁ and M₂ are connected to each other in series at a first common node “X”, and the transistors M₃ and M₄ are connected to each other in series at a second common node “Y,” in which a source terminal of the transistor M₁ and a drain terminal of the transistor M₂ are connected to each other and a drain terminal of the transistor M₃ and a source terminal of the transistor M₄ are connected to each other. Further, an input node of the charge pump circuit 200, which is configured to receive an input voltage Vᵢₙ (or a first reference voltage), is connected to a drain terminal the transistor M₁ and a source terminal of the transistor M₃; and an output node of the charge pump circuit 200, which is configured to provide an output voltage Vₒᵤₜ, is connected to a source terminal of the transistor M₂. A drain terminal of the transistor M₄ is connected to ground/V_{SS} (or a second reference voltage). The input node and output node may be connected to ground through capacitors Cᵢₙ and Cₒᵤₜ, respectively.

In various embodiments, each of the transistors M₁ to M₄ operatively serves as a switch, and further, a clock-controlled switch. For example, a gate terminal of the transistor M₁ is connected to a clock CLK signal; a gate terminal of the transistor M₂ is connected to a logically inverse clock CLKB signal; a gate terminal of the transistor M₃ is connected to the clock CLK signal; and a gate terminal of the transistor M₄ is connected to the logically inverse clock CLKB signal. As such, the transistor M₁, together with the transistor M₄, may be alternately turned on/off with respect to the transistor M₂, together with the transistor M₃. Stated another way, the transistors M₁ to M₄ may each operatively serve as a switch controlled by a clock signal (and its inverse one). Accordingly, the transistors M₁ to M₄ may be replaced with any of various other switches while remaining within the scope of the present disclosure.

The capacitor C_{F} is connected between the node X and node Y. Specifically, the capacitor C_{F} has a first (e.g., positive) terminal connected to the node X, and a second (e.g., negative) terminal connected to the node Y. With the coupled transistors M₁ to M₄ alternately activated, the charge pump circuit 200 can provide an output voltage as a multiply of the difference between a first reference voltage and a second reference voltage. For example in FIG. 2, the charge pump circuit 200 can provide the output voltage Vₒᵤₜ as 2×Vᵢₙ. In operation, the transistors M₁ and M₄ may first be turned on, with the transistors M₂ and M₃ turned off. As such, the first and second terminals of the capacitor C_{F} are connected to Vᵢₙ and ground, respectively, which charges up the capacitor C_{F} until a voltage across its first and second terminals is equal to Vᵢₙ. Next, the transistors M₂ and M₃ may be turned on, with the transistors M₁ and M₄ turned off. As such, the second terminal of the capacitor C_{F} is connected to Vᵢₙ, while the first terminal of the capacitor C_{F} is connected to Vₒᵤₜ. Since the voltage across a capacitor cannot immediately change, the capacitor C_{F} will maintain an equivalent voltage of Vᵢₙ across itself. To maintain this Vᵢₙ across itself, the capacitor C_{F} forces the voltage at the output node (Vₒᵤₜ) to be equal to 2×Vᵢₙ, making the equivalent voltage across the capacitor C_{F} equal to Vᵢₙ.

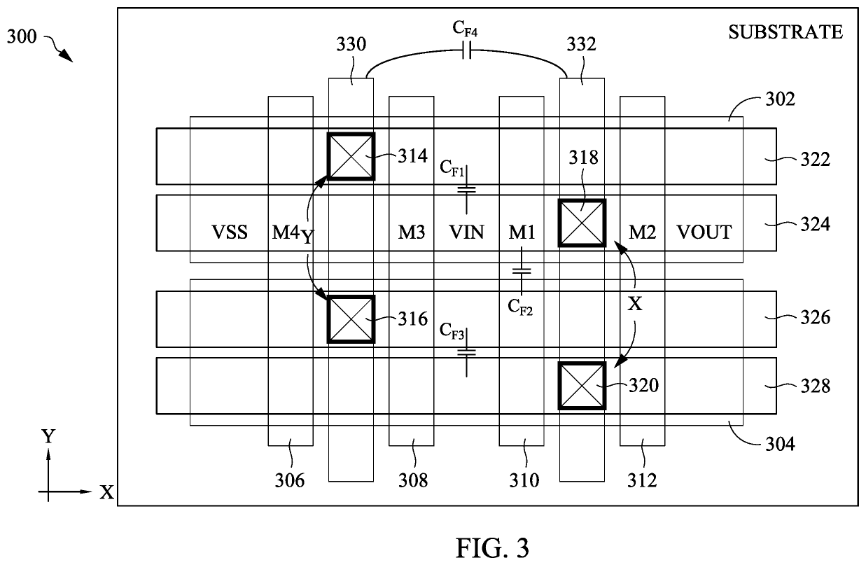

FIG. 3 illustrates a layout 300 that can be utilized to form a charge pump circuit (e.g., 200 of FIG. 2), in accordance with various embodiments. In one aspect, the layout 300 includes a number of patterns configured to form the transistors M₁ to M₄ and the capacitor C_{F}, respectively. Further, the transistors M₁ to M₄ may be formed on a first side of a substrate (e.g., frontside), while the capacitor C_{F} may be formed on a second, opposite side of the substrate (e.g., backside), which will be discussed below. It should be noted that the layout 300 is simplified for illustrative purposes, and thus, the layout 300 can include any of various other components (e.g., patterns) while remaining within the scope of the present disclosure.

As shown, the layout 300 includes patterns 302 and 304 that are each configured to form an active region (hereinafter “active region 302,” and “active region 304,” respectively); and patterns 306, 308, 310, and 312 that are each configured to form a gate structure (hereinafter “gate structure 306,” “gate structure 308,” “gate structure 310,” and “gate structure 312,” respectively). In some embodiments, the active regions 302 to 304 may each extend along a first lateral direction (e.g., X-direction), and the gate structures 306 to 312 may each extend along a second, different lateral direction (e.g., Y-direction). It should be understood that the layout 300 can include any number of each of the active regions and gate structures, while remaining within the scope of present disclosure.

In some embodiments, each of the active regions 302 to 304 is formed of a stack structure protruding from a major (e.g., frontside) surface of a substrate. The stack includes a number of semiconductor nanostructures (e.g., nanosheets) extending along the X-direction and vertically separated from each other. Portions of the semiconductor structures in the stack that are overlaid by the gate structure remain, while other portions are replaced with a number of epitaxial structures. The remaining portions of the semiconductor structures can be configured as the channel of a corresponding transistor, the epitaxial structures coupled to both sides (or ends) of the remaining portions of the semiconductor structures can be configured as source/drain structures (or terminals) of the transistor, and a portion of the gate structure that overlays (e.g., straddles) the remaining portions of the semiconductor structures can be configured as a gate structures (or terminal) of the transistor.

For example in FIG. 3, the portion of the active region 302 that is overlaid by the gate structure 306 may include a number of nanostructures vertically separated from each other, which can function as the channel of a first sub-transistor. The portions of the active region 302 that are disposed on opposite sides of the gate structure 306 are replaced with epitaxial structures. Such epitaxial structures can function as source/drain terminals of the first sub-transistor. The gate structure 306 can function as a gate terminal of the first sub-transistor. A second sub-transistor can be formed by the active region 304 and the same gate structure 306. Such first and second sub-transistors (coupled to each other in parallel) can collectively form the transistor M₄. Similarly, transistors M₁ to M₃ can be formed by respective active regions and gate structures, as indicated in FIG. 3.

With the transistors M₁ to M₄ formed by the active regions 302-304 and gate structures 306-312, the node X can be formed by (or coupled to) the portion of the active region 302 interposed between the gate structures 310-312, and the portion of the active region 304 interposed between the gate structures 310-312; and the node Y can be formed by (or coupled to) the portion of the active region 302 interposed between the gate structures 306-308, and the portion of the active region 304 interposed between the gate structures 306-308. Further, the portion of the active region 302 interposed between the gate structures 308-310 and the portion of the active region 304 interposed between the gate structures 308-310 can be coupled to the input node/first reference voltage (Vᵢₙ); the portion of the active region 302 opposite the gate structure 306 from the interposed portion between the gate structures 308-308 and the portion of the active region 304 opposite the gate structure 306 from the interposed portion between the gate structures 308-308 can be coupled to the second reference voltage (ground); and the portion of the active region 302 opposite the gate structure 312 from the interposed portion between the gate structures 310-312 and the portion of the active region 304 opposite the gate structure 312 from the interposed portion between the gate structures 310-312 can be coupled to the output node (Vₒᵤₜ).

To electrically connect each of these transistors to one or more respective nodes or signals, the layout 300 can further include a number of patterns (not shown) that are each configured to form a frontside metal structure/track. In some embodiments, these frontside metal tracks are formed across a plural number of frontside metallization layers disposed over the frontside surface of the substrate. Such frontside metallization layers are sometimes referred to as M0 layer, M1 layer, M2 layer, etc., where the M0 layer may be the closest one to the major surface of the substate. Each of the frontside metallization layers includes a number of metal tracks embedded in one or more corresponding inter-layer dielectric (ILD) materials or inter-metal dielectric (IMD) materials. The metal track in a corresponding metallization layer (e.g., M0 layer) may sometimes be referred to as an M0 track. In some embodiments, the input node (Vᵢₙ), output node (Vₒᵤₜ), ground node (GND/V_{SS}) can each be coupled to or carried by a metal track in a corresponding one of the metallization layers, and the gate structures 306 to 312 can each be coupled to a metal track that carries a clock signal or its inverse.

The layout 300 further includes patterns 314, 316, 318, and 320 that are each configured to form a via structure (hereinafter “via structure 314,” “via structure 316,” “via structure 318,” and “via structure 320,” respectively); patterns 322, 324, 326, and 328 that are each configured to form a backside metal track (hereinafter “metal track 322,” “metal track 324,” “metal track 326,” and “metal track 328,” respectively); and patterns 330 and 332 that are each configured to form a backside metal track (hereinafter “metal track 330,” and “metal track 332,” respectively). The via structures 314 to 320 can each extend partially through the substrate to electrically couple one of the source/drain terminals (formed on the frontside) to a corresponding backside metal track. Such via structures 314 to 320 may sometimes be referred to as VB structures. Similar to the frontside, over the backside of the substrate, a plurality of backside metallization layers can be formed, which are sometimes referred to as BM0 layer, BM1 layer, BM2 layer, etc. Each of the backside metallization layers includes a number of metal tracks embedded in one or more corresponding inter-layer dielectric (ILD) materials or inter-metal dielectric (IMD) materials. The metal tracks 322 to 328 may be formed in the BM0 layer, and the metal tracks 330 to 332 may be formed in the BM1 layer. Accordingly, the metal tracks 322 to 328 may sometimes be referred to as BM0 metal tracks, and the metal tracks 330 to 332 may sometimes be referred to as BM1 metal tracks.

In some embodiments, the via structures 314 and 316 can couple the node Y to the metal tracks 322 and 326, respectively; and the via structures 318 and 320 can couple the node X to the metal tracks 324 and 328. The via structures 318 and 320 (or the respective portions of the metal tracks 324 and 328 coupled to the active regions on the frontside) may be aligned with each other along the Y-direction, and the via structures 314 and 316 (or the respective portions of the metal tracks 322 and 326 coupled to the active regions on the frontside) may be aligned with each other along the Y-direction.

The metal tracks 324 and 328 can collectively function as the first (positive) terminal of the capacitor C_{F}, and the metal tracks 322 and 326 can collectively function as the second (negative) terminal of the capacitor C_{F}. The metal tracks coupled to the positive terminal of the capacitor C_{F} (sometimes referred to as positive tracks) and the metal tracks coupled to the negative terminal of the capacitor C_{F} (sometimes referred to as negative tracks) may be alternately arranged with respect to one another along the Y-direction. For example in FIG. 3, each of the positive tracks (e.g., 324, 328) is interposed between adjacent negative tracks (e.g., 322, 326) along the Y-direction or disposed next to a negative track along the Y-direction. Alternatively stated, the via structures 318 and 320 can couple the source terminal of the transistor M₁ and the drain terminal of the transistor M₂ to the first (positive) terminal of the capacitor C_{F}; and the via structures 314 and 316 can couple the drain terminal of the transistor M₃ and the source terminal of the transistor M₄ to the second (negative) terminal of the capacitor C_{F}.

By alternately arranging the plural positive tracks and negative tracks, a plural number of sub-capacitors can be formed to serve as the capacitor C_{F}. For example in FIG. 3, a first sub-capacitor, C_{F1}, can be formed by the negative track 322 and the positive track 324, and the IMD/ILD material interposed therebetween; a second sub-capacitor, C_{F2}, can be formed by the positive track 324 and the negative track 326, and the IMD/ILD material interposed therebetween; and a third sub-capacitor, C_{F3}, can be formed by the negative track 326 and the positive track 328, and the IMD/ILD material interposed therebetween. In some embodiments, the sub-capacitors, C_{F1} to C_{F3}, can be coupled to one another in parallel to form the capacitor C_{F}, that is, C_{F}=C_{F1}+C_{F2}+C_{F3}. Although four positive/negative metal tracks are shown in the BM0 layer, it should be appreciated that the layout 300 can include any number of positive tracks and negative tracks in the BM0 layer to form the capacitor C_{F}. Accordingly, the capacitor C_{F} can be a sum of any corresponding number of sub-capacitors in the BM0 layer.

Additionally, the capacitor C_{F} can be further formed by positive/negative tracks in one or more other backside metallization layers, in some embodiments. For example, the metal track 332 in the BM1 layer can be coupled to the positive terminal of the capacitor C_{F} (node X), which accordingly functions as another positive track; and the metal track 330 in the BM1 layer can be coupled to the negative terminal of the capacitor C_{F} (node Y), which accordingly functions as another negative track. As such, the metal tracks 330 and 332, together with the IMD/ILD material interposed therebetween, can function as another sub-capacitor, C_{F4}, of the capacitor C_{F}.

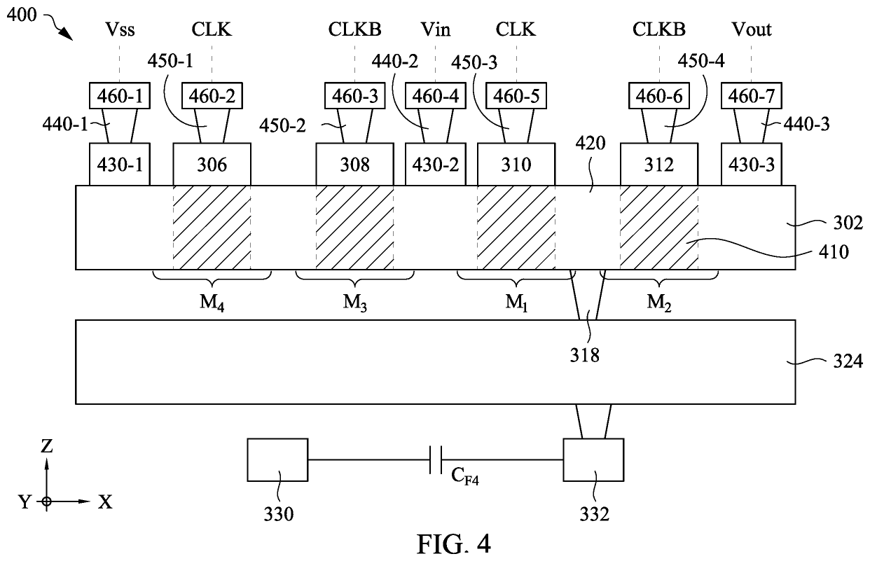

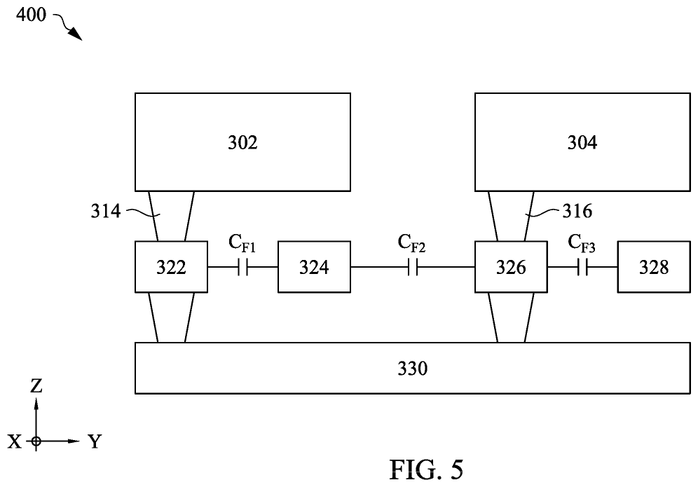

FIGS. 4 and 5 respectively illustrate cross-sectional views of a semiconductor device 400 formed based on the layout 300 of FIG. 3, in accordance with some embodiments of the present disclosure. Accordingly, the semiconductor device 400 can include at least four switches formed on the frontside of a substrate, each of which is formed as a clock-controller transistor (e.g., the transistors M₁ to M₄), and a fly capacitor (e.g., the capacitor C_{F}) formed on a backside of the substrate. The cross-sectional view of FIG. 4 is cut along a lengthwise direction of the active region above the positive track 324 (e.g., the X-direction), and the cross-sectional view of FIG. 5 is cut along a lengthwise direction of the gate structure between the gate structures 306 and 308 (e.g., the Y-direction).

Referring first to FIG. 4, along the active region 302, a number of channels 410 and epitaxial structures 420 can be formed. Each of the channels 410 can be overlaid or wrapped by a corresponding one of the gate structures, e.g., 306, 308, 310, 312, and some of the epitaxial structures can be overlaid by a corresponding MD, e.g., 430. In some embodiments, the MD is a metal track formed on the frontside coupling a corresponding source/drain terminal (e.g., an epitaxial structure) to a higher metal track, e.g., M0 track 460, through a VD, e.g., 440. Further, each of the gate structures can be coupled to a higher metal track, e.g., M0 track 460, through a VG, e.g., 450.

For example, the transistor M₄ has one of its source/drain terminals coupled to an M0 track 460-1 (e.g., carrying GND/V_{SS}) through an MD 430-1 and a VD 440-1; the transistor M₄ has its gate terminal 306 coupled to an M0 track 460-2 (e.g., coupled to a CLK signal) through a VG 450-1; the transistor M₃ has its gate terminal 308 coupled to an M0 track 460-3 (e.g., coupled to a CLKB signal) through a VG 450-2; the transistor M₃ has one of its source/drain terminals coupled to an M0 track 460-4 (e.g., carrying Vᵢₙ) through an MD 430-2 and a VD 440-2; the transistor M₁ has its gate terminal 310 coupled to an M0 track 460-5 (e.g., coupled to the CLK signal) through a VG 450-3; the transistor M₂ has its gate terminal 312 coupled to an M0 track 460-6 (e.g., coupled to the CLKB signal) through a VG 450-4; and the transistor M₂ has one of its source/drain terminals coupled to an M0 track 460-7 (e.g., carrying Vₒᵤₜ) through an MD 430-3 and a VD 440-4.

On the backside of the substrate (or the active region 302), the positive track 324 is shown, which is couped to the common source/drain terminal connecting the transistors M₁ and M₂ through the VB 318, as shown in FIG. 4. Although not shown, it should be understood that the other positive track 328 (FIG. 3) is also formed on the backside of the substrate (or the active region 304), and coupled to the common source/drain terminal connecting the transistors M₁ and M₂ through the VB 320. In FIG. 4, the semiconductor device 400 further includes the negative track 330 and positive track 332 formed in the BM1 layer, where the positive track 332 in the BM1 layer is coupled to the positive track 324 in the BM0 layer through a via structure while the negative track 330 in the BM1 layer is not coupled to the positive track 324 in the BM0 layer. In some embodiments, the positive track 332 and negative track 330 operatively form the sub-capacitor C_{F4}, as indicated.

In the cross-sectional view of FIG. 5 (cut along the Y-direction between the gate structures 306 and 308), the negative tracks 322 and 326 are shown as being coupled to the active regions 302 and 304 (or the source/drain terminals of the transistors M₃ and M₄) through the VBs 314 and 316, respectively. With the negative tracks, 322 and 326, and the positive tracks, 324 and 328, alternately arranged with each other, the sub-transistors, C_{F1}, C_{F2}, C_{F3}, can be formed, as indicated. Although not shown, it should be understood that, in a cross-sectional view cut along the Y-direction between the gate structures 310 and 312, the positive tracks 324 and 328 are coupled to the active regions 302 and 304 (or the source/drain terminals of the transistors M₁ and M₂) through the VBs 318 and 320, respectively.

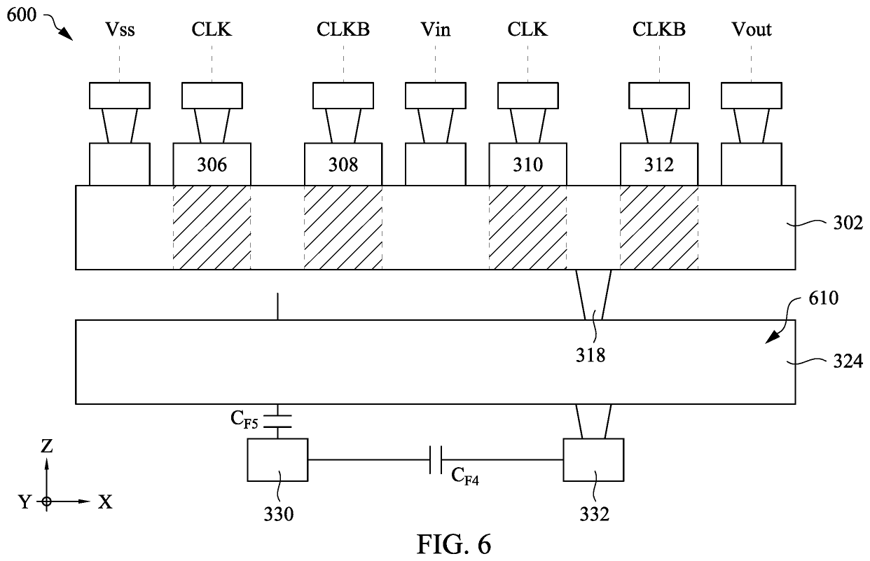

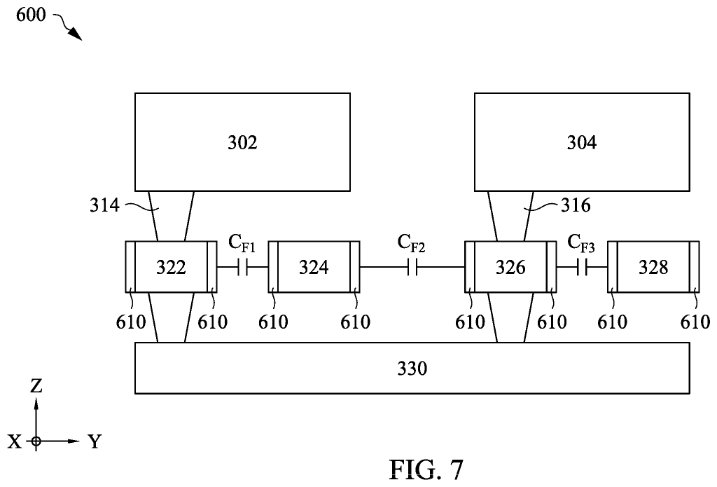

FIGS. 6 and 7 respectively illustrate cross-sectional views of another semiconductor device 600 formed based on the layout 300 of FIG. 3, in accordance with some embodiments of the present disclosure. Accordingly, the semiconductor device 600 can include at least four switches formed on the frontside of a substrate, each of which is formed as a clock-controller transistor (e.g., the transistors M₁ to M₄), and a fly capacitor (e.g., the capacitor C_{F}) formed on a backside of the substrate. The cross-sectional view of FIG. 6 is cut along a lengthwise direction of the active region above the positive track 324 (e.g., the X-direction), and the cross-sectional view of FIG. 7 is cut along a lengthwise direction of the gate structure between the gate structures 306 and 308 (e.g., the Y-direction).

The cross-sectional views of FIGS. 6 and 7 are substantially similar to the cross-sectional views of FIGS. 4 and 5, respectively, except that the semiconductor device 600 further includes a high-k dielectric material formed on sidewalls of each of the positive/negative tracks of the capacitor C_{F}. Thus, the following discussion will be focused on the difference. For example in FIG. 6, the semiconductor device 600 may include a high-k dielectric material 610 extending along each sidewall of the positive track 324 (facing toward or away from the Y-direction), which can be better seen in the cross-sectional view of FIG. 7. As shown, along each sidewall of each of the positive/negative tracks, 322 to 328, a high-k dielectric material 610 is formed. In some embodiments, with such an additional high-k dielectric material laterally interposed between a corresponding pair of positive track and negative track, a total capacitance value of the capacitor C_{F} can be further increased. Examples of the high-k dielectric material 610 include, but are not limited to, TiN, Al₂O₃, Ta₂O₅, or the like.

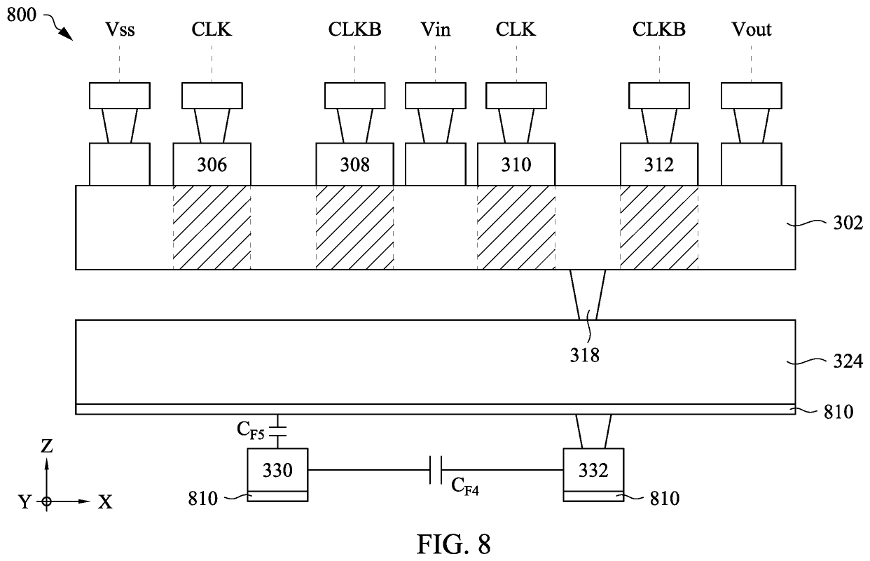

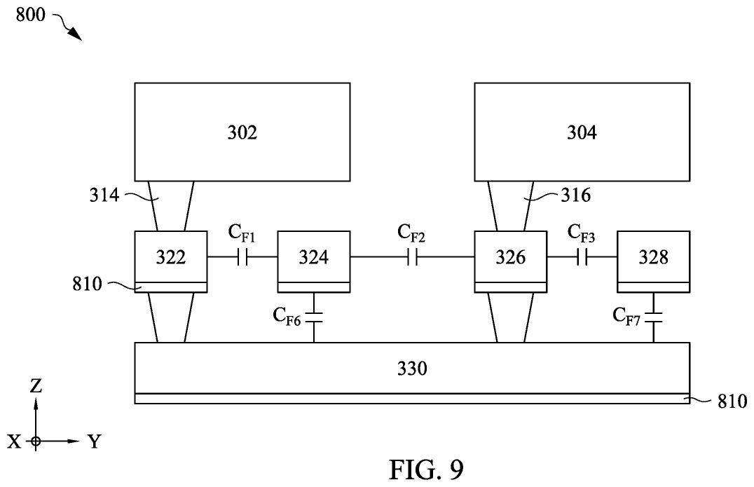

FIGS. 8 and 9 respectively illustrate cross-sectional views of another semiconductor device 800 formed based on the layout 300 of FIG. 3, in accordance with some embodiments of the present disclosure. Accordingly, the semiconductor device 800 can include at least four switches formed on the frontside of a substrate, each of which is formed as a clock-controller transistor (e.g., the transistors M₁ to M₄), and a fly capacitor (e.g., the capacitor C_{F}) formed on a backside of the substrate. The cross-sectional view of FIG. 8 is cut along a lengthwise direction of the active region above the positive track 324 (e.g., the X-direction), and the cross-sectional view of FIG. 9 is cut along a lengthwise direction of the gate structure between the gate structures 306 and 308 (e.g., the Y-direction).

The cross-sectional views of FIGS. 8 and 9 are substantially similar to the cross-sectional views of FIGS. 4 and 5, respectively, except that the semiconductor device 800 further includes a high-k dielectric material formed on a bottom and/or top surface of each of the positive/negative tracks of the capacitor C_{F}. Thus, the following discussion will be focused on the difference. For example in FIG. 8, the semiconductor device 800 may include a high-k dielectric material 810 extending along a bottom surface of the positive track 324, which can form another sub-capacitor C_{F5} between the positive track 324 in the BM0 layer and the negative track 330 in the BM1 layer (for the capacitor C_{F}). As further shown in FIG. 9, along each bottom surface of each of the positive/negative tracks, 322 to 330, a high-k dielectric material 810 is formed. In some embodiments, with such an additional high-k dielectric material underlying each of the positive tracks and negative tracks, a total capacitance value of the capacitor C_{F} can be further increased. For example, yet another sub-capacitor C_{F6} between the positive track 324 in the BM0 layer and the negative track 330 in the BM1 layer (for the capacitor C_{F}) and yet another sub-capacitor C_{F7} between the positive track 328 in the BM0 layer and the negative track 330 in the BM1 layer (for the capacitor C_{F}) can be formed. Examples of the high-k dielectric material 810 include, but are not limited to, TiN, Al₂O₃, Ta₂O₅, or the like.

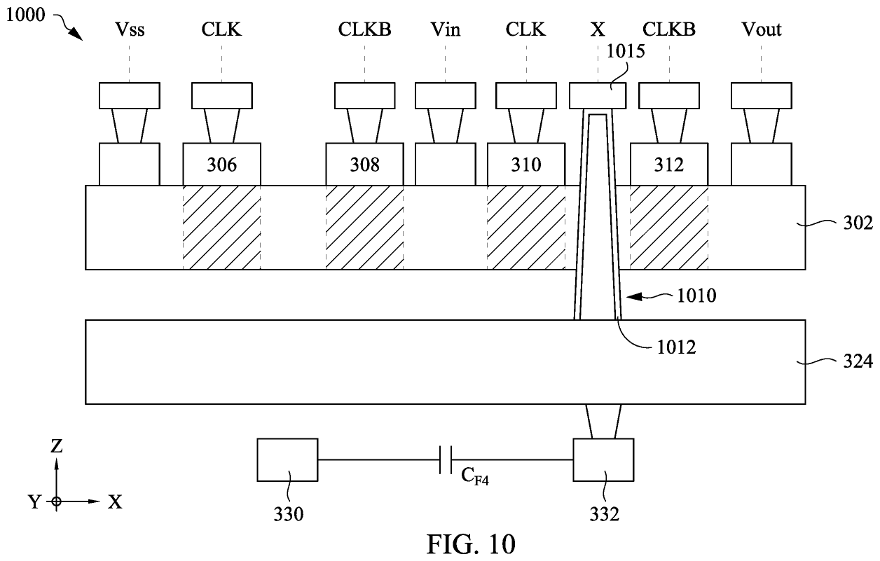

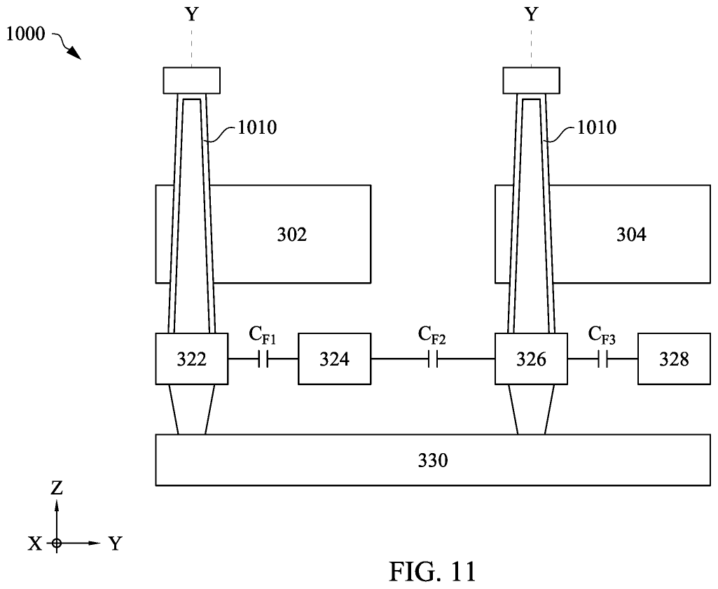

FIGS. 10 and 11 respectively illustrate cross-sectional views of another semiconductor device 1000 formed based on the layout 300 of FIG. 3, in accordance with some embodiments of the present disclosure. Accordingly, the semiconductor device 1000 can include at least four switches formed on the frontside of a substrate, each of which is formed as a clock-controller transistor (e.g., the transistors M₁ to M₄), and a fly capacitor (e.g., the capacitor C_{F}) formed on a backside of the substrate. The cross-sectional view of FIG. 10 is cut along a lengthwise direction of the active region above the positive track 324 (e.g., the X-direction), and the cross-sectional view of FIG. 11 is cut along a lengthwise of the gate structure direction between the gate structures 306 and 308 (e.g., the Y-direction).

The cross-sectional views of FIGS. 10 and 11 are substantially similar to the cross-sectional views of FIGS. 4 and 5, respectively, except that the semiconductor device 1000 further includes a number of via structures each directly coupling the positive/negative track in the BM0 layer to a corresponding M0 track. Thus, the following discussion will be focused on the difference. For example in FIG. 10, the semiconductor device 1000 includes a via structure 1010 coupling the positive track 324 in the BM0 layer to an M0 track 1015. In some embodiments, the via structure 1010 can extend from the positive track 324, through the substate (or the active region 302), and to the M0 track 1015, which can be configured as the node X (the positive terminal of the capacitor C_{F}). The via structure 1010 can have a liner 1012 lining sidewalls and a top surface of the via structure 1010. Although not shown, it should be understood that the semiconductor device 1000 can include another similar via structure coupling the other positive track 328 to another M0 track. As further shown in FIG. 11, each of the negative tracks 322 and 326 can be coupled to a corresponding M0 track configured as the node Y (the negative terminal of the capacitor C_{F}) through a respective via structure 1010.

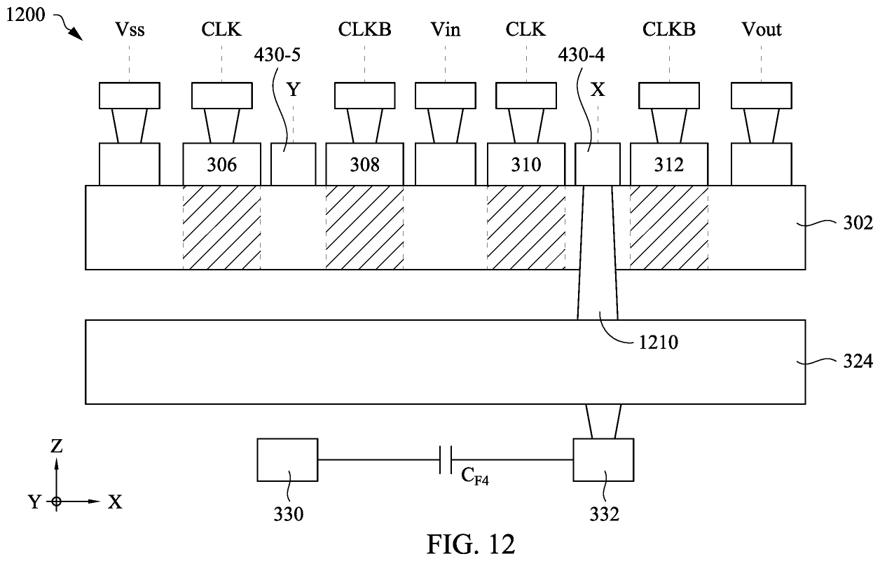

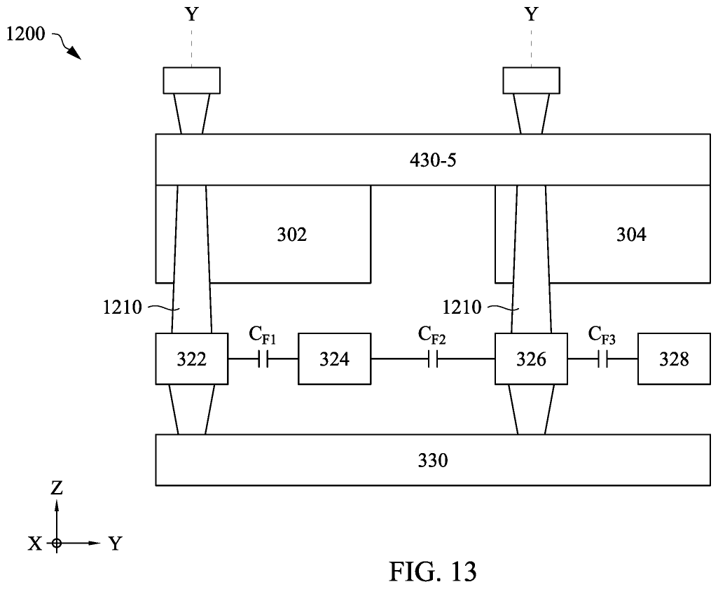

FIGS. 12 and 13 respectively illustrate cross-sectional views of another semiconductor device 1200 formed based on the layout 300 of FIG. 3, in accordance with some embodiments of the present disclosure. Accordingly, the semiconductor device 1200 can include at least four switches formed on the frontside of a substrate, each of which is formed as a clock-controller transistor (e.g., the transistors M₁ to M₄), and a fly capacitor (e.g., the capacitor C_{F}) formed on a backside of the substrate. The cross-sectional view of FIG. 12 is cut along a lengthwise direction of the active region above the positive track 324 (e.g., the X-direction), and the cross-sectional view of FIG. 13 is cut along a lengthwise direction of the gate structure between the gate structures 306 and 308 (e.g., the Y-direction).

The cross-sectional views of FIGS. 12 and 13 are substantially similar to the cross-sectional views of FIGS. 4 and 5, respectively, except that the semiconductor device 1200 further includes a number of via structures each directly coupling the positive/negative track in the BM0 layer to a corresponding MD. Thus, the following discussion will be focused on the difference. For example in FIG. 12, the semiconductor device 1200 includes a via structure 1210 coupling the positive track 324 in the BM0 layer to an MD 430-4 formed over the active region 302 (or a source/drain terminal). In some embodiments, the via structure 1210 can extend from the positive track 324, through the substate (or the active region 302), and to the MD 430-4, which can be configured as the node X (the positive terminal of the capacitor C_{F}). Although not shown, it should be understood that the semiconductor device 1200 can include another similar via structure coupling the other positive track 328 to the same MD or another MD. As further shown in FIG. 13, the negative tracks 322 and 326 can be coupled to a corresponding MD 430-5 configured as the node Y (the negative terminal of the capacitor C_{F}) through respective via structures 1210.

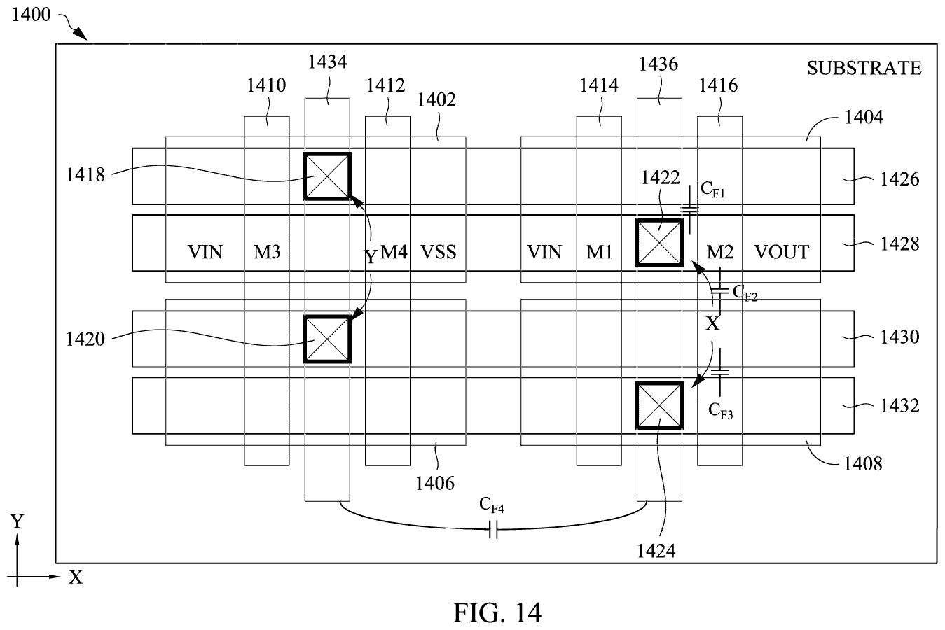

FIG. 14 illustrates another layout 1400 that can be utilized to form a charge pump circuit (e.g., 200 of FIG. 2), in accordance with various embodiments. In one aspect, the layout 1400 includes a number of patterns configured to form the transistors M₁ to M₄ and the capacitor C_{F}, respectively. Further, the transistors M₁ to M₄ may be formed on a first side of a substrate (e.g., frontside), while the capacitor C_{F} may be formed on a second, opposite side of the substrate (e.g., backside), which will be discussed below. It should be noted that the layout 1400 is simplified for illustrative purposes, and thus, the layout 1400 can include any of various other components (e.g., patterns) while remaining within the scope of the present disclosure.

As shown, the layout 1400 includes patterns 1402, 1404, 1406, and 1408 that are each configured to form an active region (hereinafter “active region 1402,” “active region 1404,” “active region 1406,” and “active region 1408,” respectively); and patterns 1410, 1412, 1414, and 1416 that are each configured to form a gate structure (hereinafter “gate structure 1410,” “gate structure 1412,” “gate structure 1414,” and “gate structure 1416,” respectively). In some embodiments, the active regions 1402 to 1408 may each extend along a first lateral direction (e.g., X-direction), and the gate structures 1410 to 1416 may each extend along a second, different lateral direction (e.g., Y-direction). Further, the active regions 1402 and 1404 may be spaced from each other along the X-direction; and the active regions 1406 and 1408 may be spaced from each other along the X-direction. It should be understood that the layout 1400 can include any number of each of the active regions and gate structures, while remaining within the scope of present disclosure.

In some embodiments, each of the active regions 1402 to 1408 is formed of a stack structure protruding from a major (e.g., frontside) surface of a substrate. The stack includes a number of semiconductor nanostructures (e.g., nanosheets) extending along the X-direction and vertically separated from each other. Portions of the semiconductor structures in the stack that are overlaid by the gate structure remain, while other portions are replaced with a number of epitaxial structures. The remaining portions of the semiconductor structures can be configured as the channel of a corresponding transistor, the epitaxial structures coupled to both sides (or ends) of the remaining portions of the semiconductor structures can be configured as source/drain structures (or terminals) of the transistor, and a portion of the gate structure that overlays (e.g., straddles) the remaining portions of the semiconductor structures can be configured as a gate structures (or terminal) of the transistor.

For example in FIG. 14, the portion of the active region 1402 that is overlaid by the gate structure 1410 may include a number of nanostructures vertically separated from each other, which can function as the channel of a first sub-transistor. The portions of the active region 1402 that are disposed on opposite sides of the gate structure 1410 are replaced with epitaxial structures. Such epitaxial structures can function as source/drain terminals of the first sub-transistor. The gate structure 1410 can function as a gate terminal of the first sub-transistor. A second sub-transistor can be formed by the active region 1406 and the same gate structure 1410. Such first and second sub-transistors (coupled to each other in parallel) can collectively form the transistor M₃. Similarly, transistors M₁ M₂, and M₄ can be formed by respective active regions and gate structures, as indicated in FIG. 14.

With the transistors M₁ to M₄ formed by the active regions 1402-1408 and gate structures 1410-1416, the node Y can be formed by (or coupled to) the portion of the active region 1402 interposed between the gate structures 1410-1412, and the portion of the active region 1406 interposed between the gate structures 1410-1412; and the node X can be formed by (or coupled to) the portion of the active region 1404 interposed between the gate structures 1414-1416, and the portion of the active region 1408 interposed between the gate structures 1414-1416. Further, the portion of the active region 1404 opposite the gate structure 1410 from the interposed portion between the gate structures 1410-1412, the portion of the active region 1406 opposite the gate structure 1410 from the interposed portion between the gate structures 1410-1412, the portion of the active region 1404 opposite the gate structure 1414 from the interposed portion between the gate structures 1414-1416, and the portion of the active region 1408 opposite the gate structure 1414 from the interposed portion between the gate structures 1414-1416 can be coupled to the input node/first reference voltage (Vᵢₙ); the portion of the active region 1402 opposite the gate structure 1412 from the interposed portion between the gate structures 1410-1412 and the portion of the active region 1406 opposite the gate structure 1412 from the interposed portion between the gate structures 1410-1412 can be coupled to the second reference voltage (ground); and the portion of the active region 1404 opposite the gate structure 1416 from the interposed portion between the gate structures 1414-1416 and the portion of the active region 1408 opposite the gate structure 1416 from the interposed portion between the gate structures 1414-1416 can be coupled to the output node (Vₒᵤₜ).

To electrically connect each of these transistors to one or more respective nodes or signals, the layout 1400 can further include a number of patterns (not shown) that are each configured to form a frontside metal structure/track. In some embodiments, these frontside metal tracks are formed across a plural number of frontside metallization layers disposed over the frontside surface of the substrate. Such frontside metallization layers are sometimes referred to as M0 layer, M1 layer, M2 layer, etc., where the M0 layer may be the closest one to the major surface of the substate. Each of the frontside metallization layers includes a number of metal tracks embedded in one or more corresponding inter-layer dielectric (ILD) materials or inter-metal dielectric (IMD) materials. In some embodiments, the input node (Vᵢₙ), output node (Vₒᵤₜ), ground node (GND/V_{SS}) can each be coupled to or carried by a metal track in a corresponding one of the metallization layers, and the gate structures 1410 to 1416 can each be coupled to a metal track that carries a clock signal or its inverse.

The layout 1400 further includes patterns 1418, 1420, 1422, and 1424 that are each configured to form a via structure (hereinafter “via structure 1418,” “via structure 1420,” “via structure 1422,” and “via structure 1424,” respectively); patterns 1426, 1428, 1430, and 1432 that are each configured to form a backside metal track (hereinafter “metal track 1426,” “metal track 1428,” “metal track 1430,” and “metal track 1432,” respectively); and patterns 1434 and 1436 that are each configured to form a backside metal track (hereinafter “metal track 1434,” and “metal track 1436,” respectively). The via structures 1418 to 1424 can each extend partially through the substrate to electrically couple one of the source/drain terminals (formed on the frontside) to a corresponding backside metal track. Such via structures 1418 to 1424 may sometimes be referred to as VB structures. Similar to the frontside, over the backside of the substrate, a plurality of backside metallization layers can be formed, which are sometimes referred to as BM0 layer, BM1 layer, BM2 layer, etc. Each of the backside metallization layers includes a number of metal tracks embedded in one or more corresponding inter-layer dielectric (ILD) materials or inter-metal dielectric (IMD) materials. The metal tracks 1426 to 1432 may be formed in the BM0 layer, and the metal tracks 1434 to 1436 may be formed in the BM1 layer. Accordingly, the metal tracks 1426 to 1432 may sometimes be referred to as BM0 metal tracks, and the metal tracks 1434 to 1436 may sometimes be referred to as BM1 metal tracks.

In some embodiments, the via structures 1418 and 1420 can couple the node Y to the metal tracks 1426 and 1430, respectively; and the via structures 1422 and 1424 can couple the node X to the metal tracks 1428 and 1432. The via structures 1422 and 1424 (or the respective portions of the metal tracks 1428 and 1432 coupled to the active regions on the frontside) may be aligned with each other along the Y-direction, and the via structures 1418 and 1420 (or the respective portions of the metal tracks 1426 and 1430 coupled to the active regions on the frontside) may be aligned with each other along the Y-direction.

The metal tracks 1428 and 1432 can collectively function as the first (positive) terminal of the capacitor C_{F}, and the metal tracks 1426 and 1430 can collectively function as the second (negative) terminal of the capacitor C_{F}. The metal tracks coupled to the positive terminal of the capacitor C_{F} (sometimes referred to as positive tracks) and the metal tracks coupled to the negative terminal of the capacitor C_{F} (sometimes referred to as negative tracks) may be alternately arranged with respect to one another along the Y-direction. For example in FIG. 14, each of the positive tracks (e.g., 1428, 1432) is interposed between adjacent negative tracks (e.g., 1426, 1430) along the Y-direction or disposed next to a negative track along the Y-direction. Alternatively stated, the via structures 1422 and 1424 can couple the source terminal of the transistor M₁ and the drain terminal of the transistor M₂ to the first (positive) terminal of the capacitor C_{F}; and the via structures 1418 and 1420 can couple the drain terminal of the transistor M₃ and the source terminal of the transistor M₄ to the second (negative) terminal of the capacitor C_{F}.

By alternately arranging the plural positive tracks and negative tracks, a plural number of sub-capacitors can be formed to serve as the capacitor C_{F}. For example in FIG. 14, a first sub-capacitor, C_{F1}, can be formed by the negative track 1426 and the positive track 1428, and the IMD/ILD material interposed therebetween; a second sub-capacitor, C_{F2}, can be formed by the positive track 1428 and the negative track 1430, and the IMD/ILD material interposed therebetween; and a third sub-capacitor, C_{F3}, can be formed by the negative track 1430 and the positive track 1432, and the IMD/ILD material interposed therebetween. In some embodiments, the sub-capacitors, C_{F1} to C_{F3}, can be coupled to one another in parallel to form the capacitor C_{F}, that is, C_{F}=C_{F1}+C_{F2}+C_{F3}. Although four positive/negative metal tracks are shown in the BM0 layer, it should be appreciated that the layout 1400 can include any number of positive tracks and negative tracks in the BM0 layer to form the capacitor C_{F}. Accordingly, the capacitor C_{F} can be a sum of any corresponding number of sub-capacitors in the BM0 layer.

Additionally, the capacitor C_{F} can be further formed by positive/negative tracks in one or more other backside metallization layers, in some embodiments. For example, the metal track 1436 in the BM1 layer can be coupled to the positive terminal of the capacitor C_{F} (node X), which accordingly functions as another positive track; and the metal track 1434 in the BM1 layer can be coupled to the negative terminal of the capacitor C_{F} (node Y), which accordingly functions as another negative track. As such, the metal tracks 1434 and 1436, together with the IMD/ILD material interposed therebetween, can function as another sub-capacitor, C_{F4}, of the capacitor C_{F}.

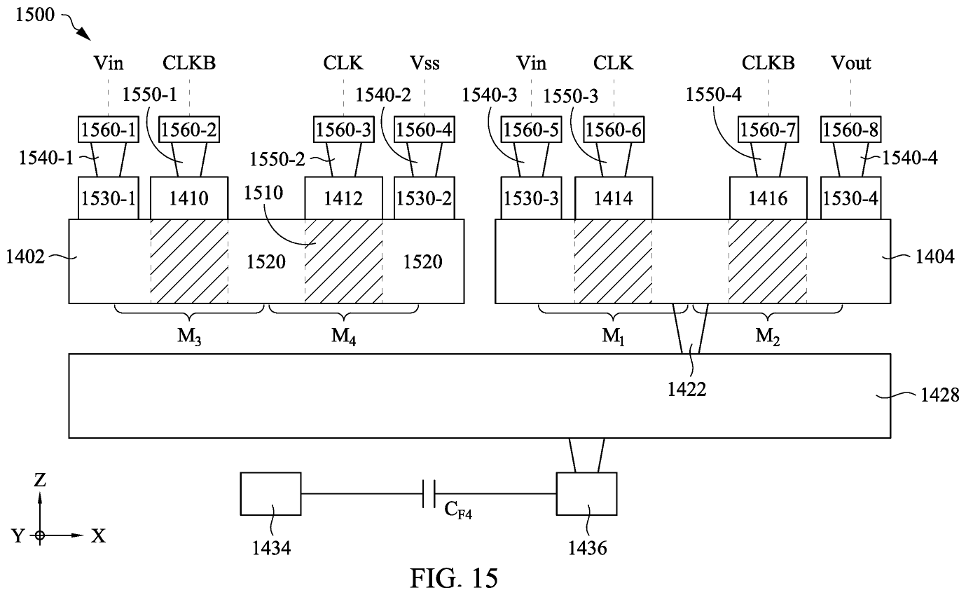

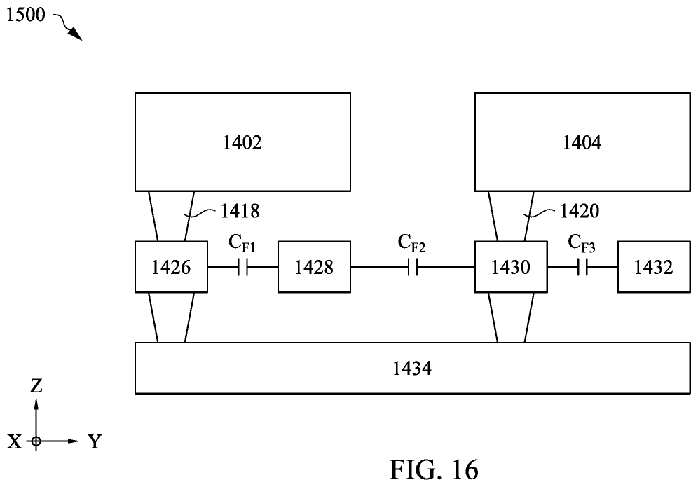

FIGS. 15 and 16 respectively illustrate cross-sectional views of a semiconductor device 1500 formed based on the layout 1400 of FIG. 14, in accordance with some embodiments of the present disclosure. Accordingly, the semiconductor device 1500 can include at least four switches formed on the frontside of a substrate, each of which is formed as a clock-controller transistor (e.g., the transistors M₁ to M₄), and a fly capacitor (e.g., the capacitor C_{F}) formed on a backside of the substrate. The cross-sectional view of FIG. 15 is cut along a lengthwise direction of the active regions above the positive track 1428 (e.g., the X-direction), and the cross-sectional view of FIG. 16 is cut along a lengthwise direction of the gate structure between the gate structures 1410 and 1412 (e.g., the Y-direction).

Referring first to FIG. 15, along each of the active regions 1402-1404, a number of channels 1510 and epitaxial structures 1520 can be formed. Each of the channels 1510 can be overlaid or wrapped by a corresponding one of the gate structures, e.g., 1410, 1424, 1414, 1416, and some of the epitaxial structures can be overlaid by a corresponding MD, e.g., 1530. In some embodiments, the MD is a metal track formed on the frontside coupling a corresponding source/drain terminal (e.g., an epitaxial structure) to a higher metal track, e.g., M0 track 1560, through a VD, e.g., 1540. Further, each of the gate structures can be coupled to a higher metal track, e.g., M0 track 1560, through a VG, e.g., 1550.

For example, the transistor M₃ has one of its source/drain terminals coupled to an M0 track 1560-1 (e.g., carrying Vᵢₙ) through an MD 1530-1 and a VD 1540-1; the transistor M₃ has its gate terminal 1410 coupled to an M0 track 1560-2 (e.g., coupled to a CLKB signal) through a VG 1550-1; the transistor M₄ has its gate terminal 1412 coupled to an M0 track 1560-3 (e.g., coupled to a CLK signal) through a VG 1550-2; the transistor M₄ has one of its source/drain terminals coupled to an M0 track 1560-4 (e.g., carrying GND/V_{SS}) through an MD 1530-2 and a VD 1540-2; the transistor M₁ has one of its source/drain terminals coupled to an M0 track 1560-5 (e.g., carrying Vᵢₙ) through an MD 1530-3 and a VD 1540-3; the transistor M₁ has its gate terminal 1414 coupled to an M0 track 1560-6 (e.g., coupled to the CLK signal) through a VG 1550-3; the transistor M₂ has its gate terminal 1416 coupled to an M0 track 1560-7 (e.g., coupled to the CLKB signal) through a VG 1550-4; and the transistor M₂ has one of its source/drain terminals coupled to an M0 track 1560-8 (e.g., carrying Vₒᵤₜ) through an MD 1530-4 and a VD 1540-4.

On the backside of the substrate (or the active regions 1402-1404), the positive track 1428 is shown, which is couped to the common source/drain terminal connecting the transistors M₁ and M₂ through the VB 1422, as shown in FIG. 15. Although not shown, it should be understood that the other positive track 1432 (FIG. 14) is also formed on the backside of the substrate (or the active regions 1406-1408), and coupled to the common source/drain terminal connecting the transistors M₁ and M₂ through the VB 1424. In FIG. 15, the semiconductor device 1500 further includes the negative track 1434 and positive track 1436 formed in the BM1 layer, where the positive track 1436 in the BM1 layer is coupled to the positive track 1428 in the BM0 layer through a via structure while the negative track 1434 in the BM1 layer is not coupled to the positive track 1428 in the BM0 layer. In some embodiments, the positive track 1436 and negative track 1434 operatively form the sub-capacitor C_{F4}, as indicated.

In the cross-sectional view of FIG. 16 (cut along the Y-direction between the gate structures 1410 and 1412), the negative tracks 1426 and 1430 are shown as being coupled to the active regions 1402 and 1404 (or the source/drain terminals of the transistors M₃ and M₄) through the VBs 1418 and 1420, respectively. With the negative tracks, 1426 and 1430, and the positive tracks, 1428 and 1432, alternately arranged with each other, the sub-transistors, C_{F1}, C_{F2}, C_{F3}, can be formed, as indicated. Although not shown, it should be understood that, in a cross-sectional view cut along the Y-direction between the gate structures 1414 and 1416, the positive tracks 1428 and 1432 are coupled to the active regions 1404 and 1408 (or the source/drain terminals of the transistors M₁ and M₂) through the VBs 1422 and 1424, respectively.

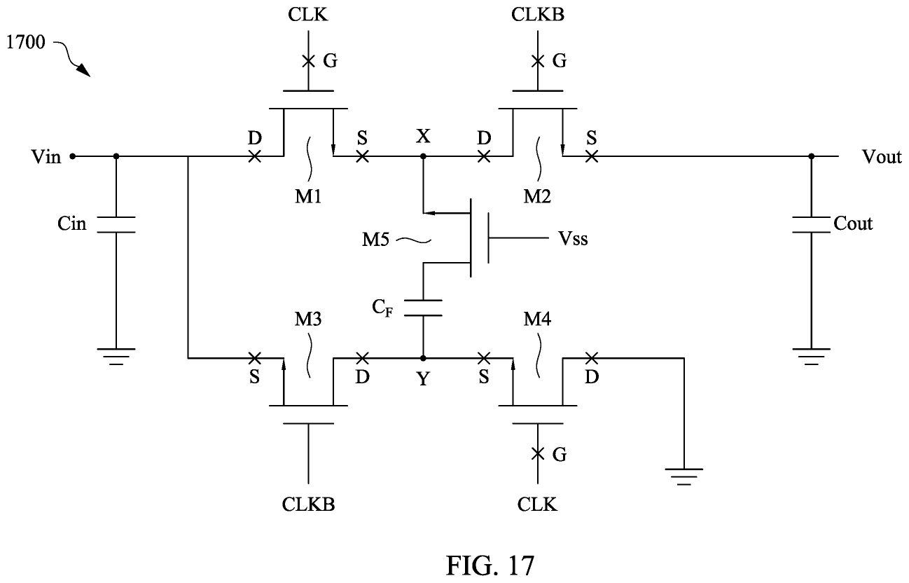

FIG. 17 illustrates an example schematic diagram 1700 of the charge pump circuit of the voltage provision circuit 110 (FIG. 1), in accordance with various embodiments. Hereinafter, the charge pump circuit shown in FIG. 17 is referred to as charge pump circuit 1700. It should be appreciated that the schematic diagram 1700 of FIG. 15 is simplified for illustrative purposes, and thus, the charge pump circuit of the voltage provision circuit 110 can be implemented as any of various other configurations (as long as it can boost an input voltage to a higher voltage level through a capacitor) while remaining within the scope of the present disclosure.

In some embodiments, the charge pump circuit 1700 is substantially similar to the charge pump circuit 200, except that the charge pump circuit 1700 further includes a transistor M₅ connected to the capacitor C_{F} in series. Accordingly, the following discussion of the charge pump circuit 1500 will be focused on the difference. For example, the capacitor C_{F} is connected between the node X and node Y with the transistor M₅ coupled between itself or either one of the node X or Y. As such, the capacitor C_{F} has a first (e.g., positive) terminal coupled to the node X through the transistor M₅, and a second (e.g., negative) terminal connected to the node Y. In some embodiments, the transistor M₅ may be gated by a fixed voltage, e.g., ground/V_{SS}.

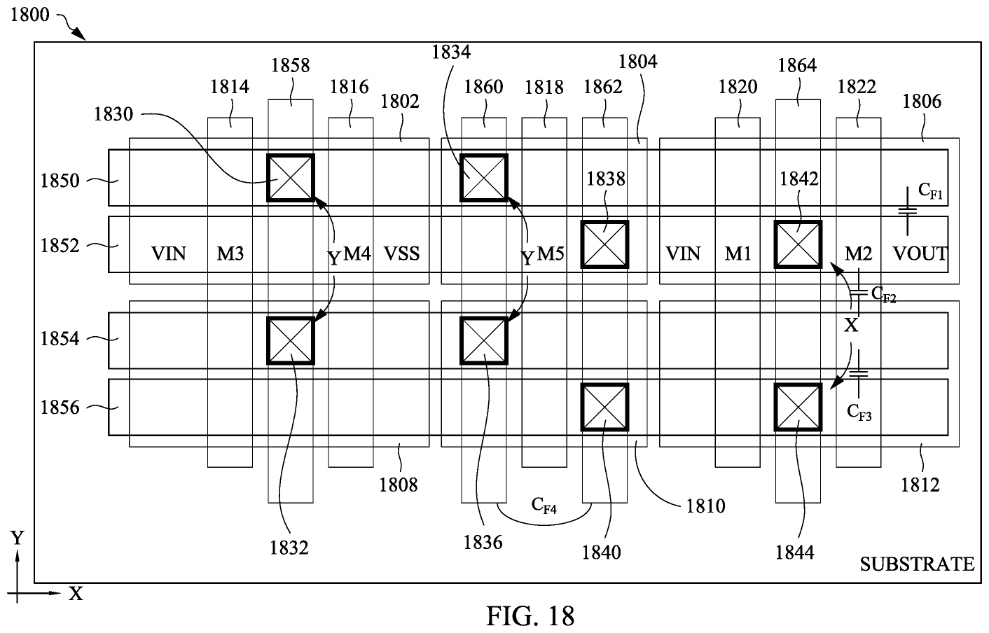

FIG. 18 illustrates a layout 1800 that can be utilized to form a charge pump circuit (e.g., 1700 of FIG. 17), in accordance with various embodiments. In one aspect, the layout 1800 includes a number of patterns configured to form the transistors M₁ to M₅ and the capacitor C_{F}, respectively. Further, the transistors M₁ to M₅ may be formed on a first side of a substrate (e.g., frontside), while the capacitor C_{F} may be formed on a second, opposite side of the substrate (e.g., backside), which will be discussed below. It should be noted that the layout 1800 is simplified for illustrative purposes, and thus, the layout 1800 can include any of various other components (e.g., patterns) while remaining within the scope of the present disclosure.

As shown, the layout 1800 includes patterns 1802, 1804, 1806, 1808, 1810, and 1812 that are each configured to form an active region (hereinafter “active region 1802,” “active region 1804,” “active region 1806,” “active region 1808,” “active region 1810,” and “active region 1812,” respectively); and patterns 1814, 1816, 1818, 1820, and 1822 that are each configured to form a gate structure (hereinafter “gate structure 1814,” “gate structure 1816,” “gate structure 1816,” “gate structure 1818,” “gate structure 1820,” and “gate structure 1822,” respectively). In some embodiments, the active regions 1802 to 1812 may each extend along a first lateral direction (e.g., X-direction), and the gate structures 1814 to 1822 may each extend along a second, different lateral direction (e.g., Y-direction). Further, the active regions 1802, 1804, and 1806 may be spaced from each other along the X-direction; and the active regions 1808, 1810, and 1812 may be spaced from each other along the X-direction. It should be understood that the layout 1800 can include any number of each of the active regions and gate structures, while remaining within the scope of present disclosure.

In some embodiments, each of the active regions 1802 to 1812 is formed of a stack structure protruding from a major (e.g., frontside) surface of a substrate. The stack includes a number of semiconductor nanostructures (e.g., nanosheets) extending along the X-direction and vertically separated from each other. Portions of the semiconductor structures in the stack that are overlaid by the gate structure remain, while other portions are replaced with a number of epitaxial structures. The remaining portions of the semiconductor structures can be configured as the channel of a corresponding transistor, the epitaxial structures coupled to both sides (or ends) of the remaining portions of the semiconductor structures can be configured as source/drain structures (or terminals) of the transistor, and a portion of the gate structure that overlays (e.g., straddles) the remaining portions of the semiconductor structures can be configured as a gate structures (or terminal) of the transistor.

For example in FIG. 18, the portion of the active region 1802 that is overlaid by the gate structure 1814 may include a number of nanostructures vertically separated from each other, which can function as the channel of a first sub-transistor. The portions of the active region 1802 that are disposed on opposite sides of the gate structure 1814 are replaced with epitaxial structures. Such epitaxial structures can function as source/drain terminals of the first sub-transistor. The gate structure 1814 can function as a gate terminal of the first sub-transistor. A second sub-transistor can be formed by the active region 1808 and the same gate structure 1814. Such first and second sub-transistors (coupled to each other in parallel) can collectively form the transistor M₃. Similarly, transistors M₁ M₂, M₄, and M₅ can be formed by respective active regions and gate structures, as indicated in FIG. 18.

With the transistors M₁ to M₅ formed by the active regions 1802-1812 and gate structures 1814-1822, the node Y can be formed by (or coupled to) the portion of the active region 1802 interposed between the gate structures 1814-1816, the portion of the active region 1808 interposed between the gate structures 1814-1816, and the portion of the active region 1804 on the lefthand side of the gate structure 1818; and the node X can be formed by (or coupled to) the portion of the active region 1806 interposed between the gate structures 1820-1822, the portion of the active region 1812 interposed between the gate structures 1820-1822, and the portion of the active region 1804 on the righthand side of the gate structure 1818.

Further, the portion of the active region 1802 opposite the gate structure 1814 from the interposed portion between the gate structures 1814-1816, the portion of the active region 1808 opposite the gate structure 1814 from the interposed portion between the gate structures 1814-1816, the portion of the active region 1806 opposite the gate structure 1820 from the interposed portion between the gate structures 1820-1822, and the portion of the active region 1812 opposite the gate structure 1820 from the interposed portion between the gate structures 1820-1822 can be coupled to the input node/first reference voltage (Vᵢₙ); the portion of the active region 1802 opposite the gate structure 1816 from the interposed portion between the gate structures 1814-1816 and the portion of the active region 1808 opposite the gate structure 1816 from the interposed portion between the gate structures 1814-1816 can be coupled to the second reference voltage (ground); and the portion of the active region 1806 opposite the gate structure 1822 from the interposed portion between the gate structures 1820-1822 and the portion of the active region 1812 opposite the gate structure 1822 from the interposed portion between the gate structures 1820-1822 can be coupled to the output node (Vₒᵤₜ).

To electrically connect each of these transistors to one or more respective nodes or signals, the layout 1800 can further include a number of patterns (not shown) that are each configured to form a frontside metal structure/track. In some embodiments, these frontside metal tracks are formed across a plural number of frontside metallization layers disposed over the frontside surface of the substrate. Such frontside metallization layers are sometimes referred to as M0 layer, M1 layer, M2 layer, etc., where the M0 layer may be the closest one to the major surface of the substate. Each of the frontside metallization layers includes a number of metal tracks embedded in one or more corresponding inter-layer dielectric (ILD) materials or inter-metal dielectric (IMD) materials. In some embodiments, the input node (Vᵢₙ), output node (Vₒᵤₜ), ground node (GND/V_{SS}) can each be coupled to or carried by a metal track in a corresponding one of the metallization layers, the gate structures 1814-1816 and 1820-1822 can each be coupled to a metal track that carries a clock signal or its inverse, and the gate structure 1818 can be coupled to a metal track that carries V_{SS}.

The layout 1800 further includes patterns 1830, 1832, 1834, 1836, 1838, 1840, 1842, and 1844 that are each configured to form a via structure (hereinafter “via structure 1830,” “via structure 1832,” “via structure 1834,” “via structure 1836,” “via structure 1838,” “via structure 1840,” “via structure 1842,” and “via structure 1844,” respectively); patterns 1850, 1852, 1854, and 1856 that are each configured to form a backside metal track (hereinafter “metal track 1850,” “metal track 1852,” “metal track 1854,” and “metal track 1856,” respectively); and patterns 1858, 1860, 1862, and 1864 that are each configured to form a backside metal track (hereinafter “metal track 1858,” “metal track 1860,” “metal track 1862,” and “metal track 1864,” respectively). The via structures 1830 to 1844 can each extend partially through the substrate to electrically couple one of the source/drain terminals (formed on the frontside) to a corresponding backside metal track. Such via structures 1830 to 1844 may sometimes be referred to as VB structures. Similar to the frontside, over the backside of the substrate, a plurality of backside metallization layers can be formed, which are sometimes referred to as BM0 layer, BM1 layer, BM2 layer, etc. Each of the backside metallization layers includes a number of metal tracks embedded in one or more corresponding inter-layer dielectric (ILD) materials or inter-metal dielectric (IMD) materials. The metal tracks 1850 to 1856 may be formed in the BM0 layer, and the metal tracks 1858 to 1864 may be formed in the BM1 layer. Accordingly, the metal tracks 1850 to 1856 may sometimes be referred to as BM0 metal tracks, and the metal tracks 1858 to 1864 may sometimes be referred to as BM1 metal tracks.

In some embodiments, the via structures 1830/1834 and 1832/1836 can couple the node Y to the metal tracks 1850 and 1854, respectively; and the via structures 1838/1842 and 1840/1844 can couple the node X to the metal tracks 1852 and 1856. The via structures 1842 and 1844 (or the respective portions of the metal tracks 1852 and 1856 coupled to the active regions on the frontside) may be aligned with each other along the Y-direction, the via structures 1838 and 1840 (or the respective portions of the metal tracks 1852 and 1856 coupled to the active regions on the frontside) may be aligned with each other along the Y-direction, the via structures 1834 and 1836 (or the respective portions of the metal tracks 1852 and 1856 coupled to the active regions on the frontside) may be aligned with each other along the Y-direction, and the via structures 1830 and 1832 (or the respective portions of the metal tracks 1850 and 1854 coupled to the active regions on the frontside) may be aligned with each other along the Y-direction.

The metal tracks 1852 and 1856 can collectively function as the first (positive) terminal of the capacitor C_{F}, and the metal tracks 1850 and 1854 can collectively function as the second (negative) terminal of the capacitor C_{F}. The metal tracks coupled to the positive terminal of the capacitor C_{F} (sometimes referred to as positive tracks) and the metal tracks coupled to the negative terminal of the capacitor C_{F} (sometimes referred to as negative tracks) may be alternately arranged with respect to one another along the Y-direction. For example in FIG. 18, each of the positive tracks (e.g., 1852, 1856) is interposed between adjacent negative tracks (e.g., 1850, 1854) along the Y-direction or disposed next to a negative track along the Y-direction. Alternatively stated, the via structures 1842 and 1844 can couple the source terminal of the transistor M₁ and the drain terminal of the transistor M₂ to the first (positive) terminal of the capacitor C_{F}; and the via structures 1830 and 1832 can couple the drain terminal of the transistor M₃ and the source terminal of the transistor M₄ to the second (negative) terminal of the capacitor C_{F}.

By alternately arranging the plural positive tracks and negative tracks, a plural number of sub-capacitors can be formed to serve as the capacitor C_{F}. For example in FIG. 18, a first sub-capacitor, C_{F1}, can be formed by the negative track 1850 and the positive track 1852, and the IMD/ILD material interposed therebetween; a second sub-capacitor, C_{F2}, can be formed by the positive track 1852 and the negative track 1854, and the IMD/ILD material interposed therebetween; and a third sub-capacitor, C_{F3}, can be formed by the negative track 1854 and the positive track 1856, and the IMD/ILD material interposed therebetween. In some embodiments, the sub-capacitors, C_{F1} to C_{F3}, can be coupled to one another in parallel to form the capacitor C_{F}, that is, C_{F}=C_{F1}+C_{F2}+C_{F3}. Although four positive/negative metal tracks are shown in the BM0 layer, it should be appreciated that the layout 1800 can include any number of positive tracks and negative tracks in the BM0 layer to form the capacitor C_{F}. Accordingly, the capacitor C_{F} can be a sum of any corresponding number of sub-capacitors in the BM0 layer.

Additionally, the capacitor C_{F} can be further formed by positive/negative tracks in one or more other backside metallization layers, in some embodiments. For example, the metal track 1862 in the BM1 layer can be coupled to the positive terminal of the capacitor C_{F} (node X), which accordingly functions as another positive track; and the metal track 1860 in the BM1 layer can be coupled to the negative terminal of the capacitor C_{F} (node Y), which accordingly functions as another negative track. As such, the metal tracks 1860 and 1862, together with the IMD/ILD material interposed therebetween, can function as another sub-capacitor, C_{F4}, of the capacitor C_{F}.

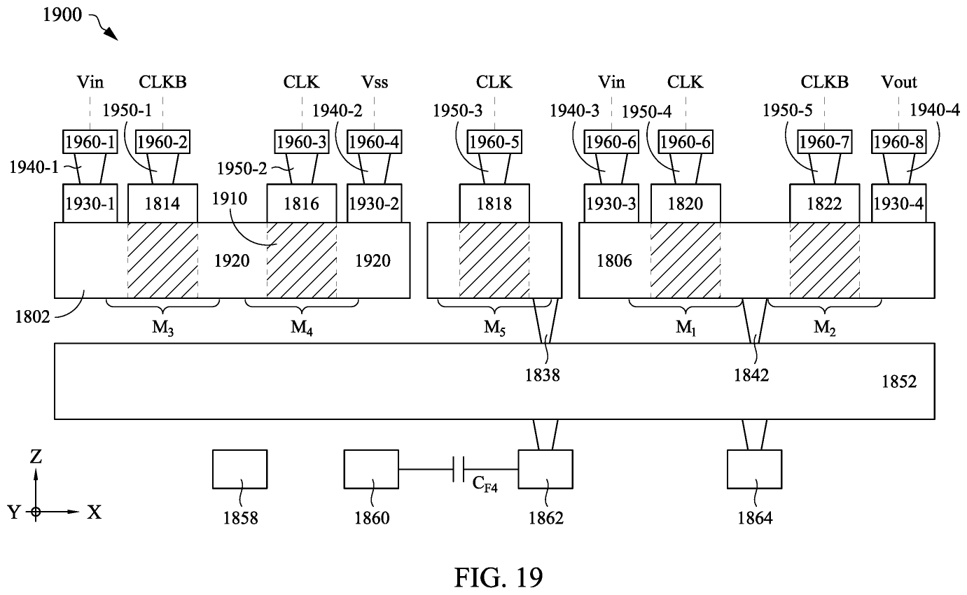

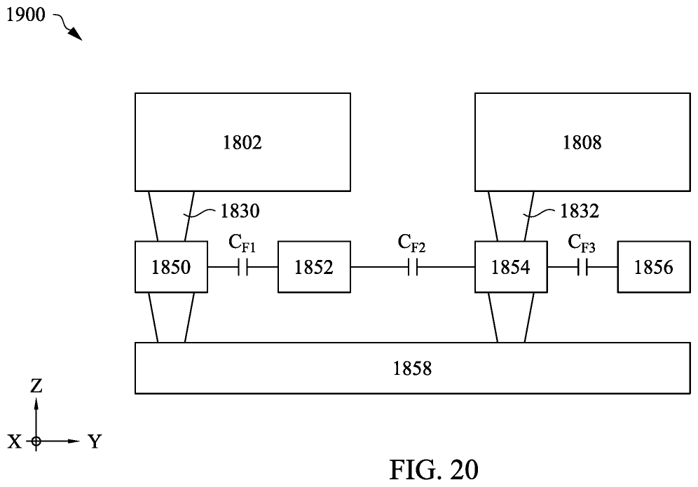

FIGS. 19 and 20 respectively illustrate cross-sectional views of a semiconductor device 1900 formed based on the layout 1800 of FIG. 18, in accordance with some embodiments of the present disclosure. Accordingly, the semiconductor device 1900 can include at least four switches formed on the frontside of a substrate, each of which is formed as a clock-controller transistor (e.g., the transistors M₁ to M₄), an always-off transistor (e.g., the transistor M₅) also formed on the frontside, and a fly capacitor (e.g., the capacitor C_{F}) formed on a backside of the substrate. The cross-sectional view of FIG. 19 is cut along a lengthwise direction of the active regions above the positive track 1852 (e.g., the X-direction), and the cross-sectional view of FIG. 20 is cut along a lengthwise direction of the gate structure between the gate structures 1814 and 1816 (e.g., the Y-direction).

Referring first to FIG. 19, along each of the active regions 1802-1806, a number of channels 1910 and epitaxial structures 1920 can be formed. Each of the channels 1910 can be overlaid or wrapped by a corresponding one of the gate structures, e.g., 1814, 1816, 1818, 1820, and 1822, and some of the epitaxial structures can be overlaid by a corresponding MD, e.g., 1930. In some embodiments, the MD is a metal track formed on the frontside coupling a corresponding source/drain terminal (e.g., an epitaxial structure) to a higher metal track, e.g., M0 track 1960, through a VD, e.g., 1940. Further, each of the gate structures can be coupled to a higher metal track, e.g., M0 track 1960, through a VG, e.g., 1950.

For example, the transistor M₃ has one of its source/drain terminals coupled to an M0 track 1960-1 (e.g., carrying Vᵢₙ) through an MD 1930-1 and a VD 1940-1; the transistor M₃ has its gate terminal 1814 coupled to an M0 track 1960-2 (e.g., coupled to a CLKB signal) through a VG 1950-1; the transistor M₄ has its gate terminal 1816 coupled to an M0 track 1960-3 (e.g., coupled to a CLK signal) through a VG 1950-2; the transistor M₄ has one of its source/drain terminals coupled to an M0 track 1960-4 (e.g., carrying GND/V_{SS}) through an MD 1930-2 and a VD 1940-2; the transistor M₅ has its gate terminal coupled to an M0 track 1960-5 through a VG 1950-3; the transistor M₁ has one of its source/drain terminals coupled to an M0 track 1960-6 (e.g., carrying Vᵢₙ) through an MD 1930-3 and a VD 1940-3; the transistor M₁ has its gate terminal 1820 coupled to an M0 track 1960-6 (e.g., coupled to the CLK signal) through a VG 1950-4; the transistor M₂ has its gate terminal 1822 coupled to an M0 track 1960-7 (e.g., coupled to the CLKB signal) through a VG 1950-5; and the transistor M₂ has one of its source/drain terminals coupled to an M0 track 1960-8 (e.g., carrying Vₒᵤₜ) through an MD 1930-4 and a VD 1940-4.

On the backside of the substrate (or the active regions 1802-1806), the positive track 1852 is shown, which is couped to the common source/drain terminal connecting the transistors M₁ and M₂ through the VB 1842 and further coupled to one of the source/drain terminals of the transistor M₅ through the VB 1838, as shown in FIG. 19. Although not shown, it should be understood that the other positive track 1856 (FIG. 18) is also formed on the backside of the substrate (or the active regions 1808-1812), and coupled to the common source/drain terminal connecting the transistors M₁ and M₂ through the VB 1844. In FIG. 19, the semiconductor device 1900 further includes the negative tracks 1858-1860 and positive tracks 1862-1864 formed in the BM1 layer, where the positive tracks 1862-1864 in the BM1 layer are each coupled to the positive track 1852 in the BM0 layer through a via structure while none of the negative tracks 1858-1860 in the BM1 layer is coupled to the positive track 1852 in the BM0 layer. In some embodiments, the positive track 1862 and negative track 1860 operatively form the sub-capacitor C_{F4}, as indicated.

In the cross-sectional view of FIG. 20 (cut along the Y-direction between the gate structures 1814 and 1816), the negative tracks 1850 and 1854 are shown as being coupled to the active regions 1802 and 1808 (or the source/drain terminals of the transistors M₃ and M₄) through the VBs 1830 and 1832, respectively. With the negative tracks, 1850 and 1854, and the positive tracks, 1852 and 1856, alternately arranged with each other, the sub-transistors, C_{F1}, C_{F2}, C_{F3}, can be formed, as indicated. Although not shown, it should be understood that, in a cross-sectional view cut along the Y-direction between the gate structures 1820 and 1822, the positive tracks 1852 and 1856 are coupled to the active regions 1806 and 1812 (or the source/drain terminals of the transistors M₁ and M₂) through the VBs 1842 and 1844, respectively; in another cross-sectional view cut along the Y-direction adjacent the gate structure 1818, the positive tracks 1852 and 1856 are coupled to the active regions 1804 and 1810 (or one of the source/drain terminals of the transistor M₅) through the VBs 1838 and 1840, respectively; and in yet another cross-sectional view cut along the Y-direction adjacent the gate structure 1818, the negative tracks 1850 and 1854 are coupled to the active regions 1804 and 1810 (or the other of the source/drain terminals of the transistor M₅) through the VBs 1834 and 1836, respectively.

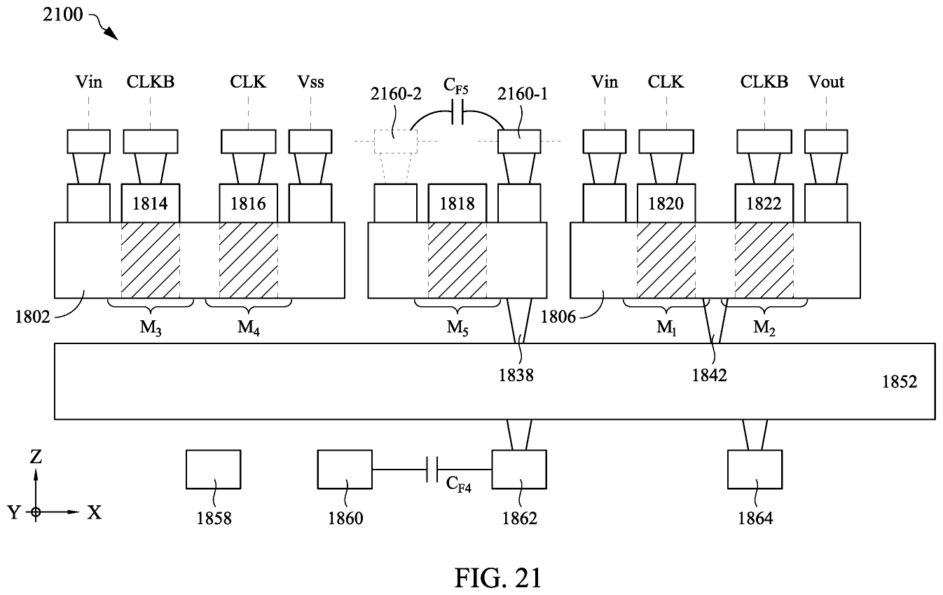

FIG. 21 illustrates a cross-sectional view of another semiconductor device 2100 formed based on the layout 1800 of FIG. 18, in accordance with some embodiments of the present disclosure. Accordingly, the semiconductor device 2100 can include at least four switches formed on the frontside of a substrate, each of which is formed as a clock-controller transistor (e.g., the transistors M₁ to M₄), an always-off transistor (e.g., the transistor M₅) also formed on the frontside, and a fly capacitor (e.g., the capacitor C_{F}) formed on a backside of the substrate. The cross-sectional view of FIG. 21 is cut along a lengthwise direction of the active regions above the positive track 1852 (e.g., the X-direction).

The cross-sectional view of FIG. 21 is substantially similar to the cross-sectional view of FIG. 19, except that the semiconductor device 2100 further includes a number of positive tracks and a number of negative tracks on the frontside that can operatively form a portion of the capacitor C_{F}. Thus, the following discussion will be focused on the difference. For example in FIG. 21, the semiconductor device 2100 may include an M0 track 2160-1 coupled to one of the source/drain terminal of the transistor M₅ through corresponding MD and VD, in which the M0 track 2160-1 may function as another positive track of the capacitor C_{F}. Further, the semiconductor device 2100 may include another M0 track 2160-2 coupled to the other of the source/drain terminal of the transistor M₅, in which the M0 track 2160-2 may function as another negative track of the capacitor C_{F}.

It is noted that the M0 track 2160-2 (and its corresponding MD and VD) is enclosed by a dotted line in FIG. 21, as the M0 track 2160-2 may only be observable in another cross-sectional view of the semiconductor device 2100 that cut along the lengthwise direction of the active regions above the negative track 1850, in some embodiments. Further, each of the M0 tracks 2160-1 and 2160-2 may be in parallel with each other. Stated another way, the M0 tracks 2160-1 and 2160-2, together with the IMD/ILD material interposed therebetween, can operatively form a portion of the capacitor C_{F} as C_{F5}.

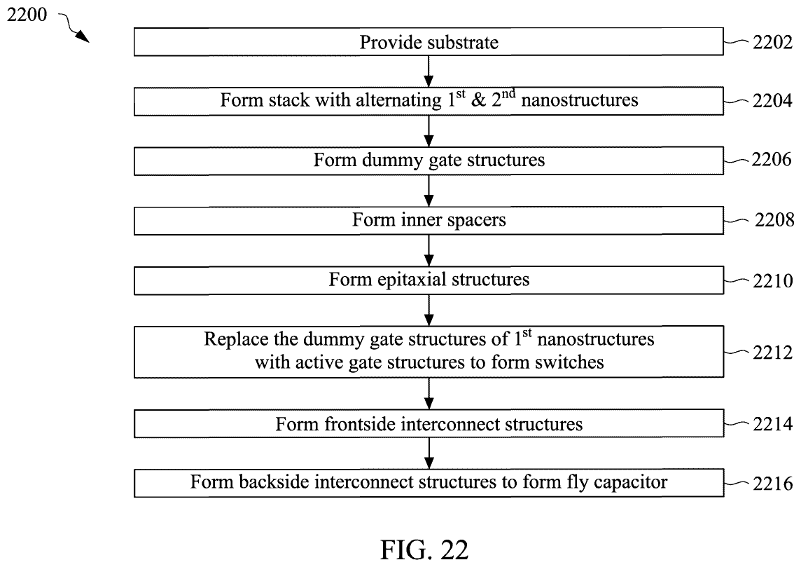

FIG. 22 illustrates a flow chart of an example method 2200 for forming a charge pump circuit with a backside fly capacitor, in accordance with some embodiments. The charge pump circuit (e.g., 200 of FIG. 2, 1700 of FIG. 17) can include at least four switches formed on the frontside of a substrate, and at least one fly capacitor formed on a backside of the substrate. In some embodiments, the method 2200 can be performed to form a charge pump circuit based on the layouts 300, 1400, and 1800 shown in FIGS. 3, 14, and 18, respectively, and thus, some of the references used above may be reused in the following discussion of the method 2200. It is noted that the method 2200 is merely an example and is not intended to limit the present disclosure. Accordingly, it is understood that additional operations may be provided before, during, and after the method 2200 of FIG. 22, and that some other operations may only be briefly described herein.

The method 2200 starts with operation 2202 in which a substrate is provided, in accordance with various embodiments. The substrate includes a semiconductor material substrate, for example, silicon. Alternatively, the substrate may include other elementary semiconductor material such as, for example, germanium. The substrate may also include a compound semiconductor such as silicon carbide, gallium arsenic, indium arsenide, and indium phosphide. The substrate may include an alloy semiconductor such as silicon germanium, silicon germanium carbide, gallium arsenic phosphide, and gallium indium phosphide. In one embodiment, the substrate includes an epitaxial layer. For example, the substrate may have an epitaxial layer overlying a bulk semiconductor. Furthermore, the substrate may include a semiconductor-on-insulator (SOI) structure. For example, the substrate may include a buried oxide (BOX) layer formed by a process such as separation by implanted oxygen (SIMOX) or other suitable technique, such as wafer bonding and grinding.

The method 2200 continues to operation 2204 in which a stack, including an alternating series of first nanostructures and second nanostructures, is formed, in accordance with various embodiments. Such a stack can be formed based on one of the (active region) patterns discussed above. The stack can be formed in a frontside of the substrate. In some embodiments, the first nanostructures may include SiGe sacrificial nanostructures, and the second nanostructures may include Si channel nanostructures. Such a stack may sometimes be referred to as a superlattice. In a non-limiting example, the SiGe sacrificial nanostructures can be SiGe 25%. The notation “SiGe 25%” is used to indicate that 25% of the SiGe material is Ge. It is understood the percentage of Ge in each of the SiGe sacrificial nanostructures can be any value between 0 and 100 (excluding 0 and 100), while remaining within the scope of present disclosure. In some other embodiments, the second nanostructures may include a first semiconductor material other than Si and the first nanostructures may include a second semiconductor material other than SiGe, as long as the first and second semiconductor materials are respectively characterized with different etching properties (e.g., etching rates).

The alternating series of nanostructures can be formed by epitaxially growing one layer and then the next until the desired number and desired thicknesses of the nanostructures are achieved. Epitaxial materials can be grown from gaseous or liquid precursors. Epitaxial materials can be grown using vapor-phase epitaxy (VPE), molecular-beam epitaxy (MBE), liquid-phase epitaxy (LPE), or other suitable process. Epitaxial silicon, silicon germanium, and/or carbon doped silicon (Si:C) silicon can be doped during deposition (in-situ doped) by adding dopants, n-type dopants (e.g., phosphorus or arsenic) or p-type dopants (e.g., boron or gallium), depending on the type of transistor.

The method 2200 continues to operation 2206 in which a number of dummy gate structures are formed, in accordance with various embodiments. Such a dummy gate structure can be formed based on one of the (gate structure) patterns discussed above. The dummy gate structure can extend along a direction perpendicular to the lengthwise direction of the dielectric fin structure (and the stack). Further, the dummy gate structure may be formed shorter than the dielectric fin structure in one of various embodiments, and thus, the dummy gate structure, as formed, is cut (or otherwise separated) by the dielectric fin structure.

The dummy gate structure can be formed by depositing amorphous silicon (a-Si) over the stack. Other materials suitable for forming dummy gates (e.g., polysilicon) can be used while remaining within the scope of present disclosure. The a-Si is then planarized to a desired level. A hard mask is deposited over the planarized a-Si and patterned. The hard mask can be formed from a nitride or an oxide layer. An etching process (e.g., a reactive-ion etching (RIE) process) is applied to the a-Si to form the dummy gate structure. After forming the dummy gate structure, gate spacers may be formed to extend along sidewalls of the dummy gate structure. The gate spacers can be formed by a conformal deposition of a dielectric material (e.g., silicon oxide, silicon nitride, silicon oxynitride, SiBCN, SiOCN, SiOC, or any suitable combination of those materials) followed by a directional etch (e.g., RIE).

The method 2200 proceeds to operation 2208 in which inner spacers are formed by replacing end portions of each of the SiGe sacrificial nanostructures with a dielectric material, in accordance with various embodiments. Upon forming the dummy gate structure overlaying certain portions of the stack (e.g., the portions of the stack separated by the dielectric fin structure), the non-overlaid portions of the stack are removed. Next, respective end portions of each SiGe sacrificial nanostructure of the overlaid stack are removed. The inner spacers are formed by filling such recesses of each SiGe sacrificial nanostructure with a dielectric material by chemical vapor deposition (CVD), or by monolayer doping (MLD) of nitride followed by spacer RIE. A material of the inner spacers can be formed from the same or different material as the gate spacers described above. For example, the inner spacers can be formed of silicon nitride, silicoboron carbonitride, silicon carbonitride, silicon carbon oxynitride, or any other type of dielectric material (e.g., a dielectric material having a dielectric constant k of less than about 5).

The method 2200 proceeds to operation 2210 in which a number of epitaxial structures are formed, in accordance with various embodiments. Upon forming the inner spacers, the epitaxial structures are formed using an epitaxial layer growth process on exposed ends of the Si nanostructures. In-situ doping (ISD) may be applied to form doped epitaxial structures, thereby creating the necessary junctions for a corresponding transistor (or sub-transistor). N-type and p-type FETs are formed by implanting different types of dopants to selected regions of the device to form the necessary junction(s). N-type devices can be formed by implanting arsenic (As) or phosphorous (P), and p-type devices can be formed by implanting boron (B). After forming the epitaxial structures, an inter-layer dielectric (e.g., silicon dioxide) is deposited to overlay the epitaxial structures.

The method 2200 proceeds to operation 2212 in which the dummy gate structures and the remaining SiGe sacrificial nanostructures are replaced with respective active gate structures, in accordance with various embodiments. Subsequently to forming the inter-layer dielectric, the dummy gate structures are removed by an etching process, e.g., RIE or chemical oxide removal (COR). Next, the remaining SiGe sacrificial nanostructures are removed while keeping the Si channel nanostructure substantially intact by applying a selective etch (e.g., a hydrochloric acid (HCl)). After the removal of the SiGe sacrificial nanostructures, top and bottom surfaces and sidewalls of each of the Si channel nanostructures can be exposed, except for the sidewall in contact with the dielectric fin structure. Next, a number of active gate structures can be formed to wrap around each of the Si channel nanostructures, except for the sidewall contacting the dielectric fin structure. Each of the active gate structures includes at least a gate dielectric layer (e.g., a high-k dielectric layer) and a gate metal layer (e.g., a work function metal layer).

Upon the active gate structures being formed, the at least four switches (e.g., the transistors M₁, M₂, M₃, and M₄) of the disclosed charge pump circuit, each of which is implemented as a clock-controlled transistor, can be formed. In some embodiments, the transistors M₁ and M₂ may be connected to each other in series, and the transistors M₃ and M₄ may be connected to each other in series. Further, the transistors M₁ and M₂ may each have a respective source/drain terminal connected to each other at a first common node (e.g., the node X), and the transistors M₃ and M₄ may each have a respective source/drain terminal connected to each other at a second common node (e.g., the node Y).

The method 2200 proceeds to operation 2214 in which a number of frontside interconnect structures are formed, in accordance with various embodiments. Upon forming the switches, a number of middle-end interconnect structures (e.g., VGs, VDs, MDs) are formed over the switches. For example, a number of VGs (e.g., 450, 1550, 1950) can be formed to connect to gate terminals of the switches, respectively, and a number of MDs (e.g., 430, 1530, 1930) can be formed to connect to source/drain terminals of the switches through a number of VDs (e.g., 440, 1540, 1940), respectively. Further, a number of back-end interconnect structures can be formed over the middle-end interconnect structures. Such back-end interconnect structures include the above-described M0 tracks (e.g., 460, 1560, 1960, 2160), and other metal tracks disposed in the upper metallization layers (e.g., M1 tracks, M2 tracks, etc.). Through the VGs, each of the switches can be gated with a clock signal or its inverse signal that conducts through one or more of the back-end metal tracks. Through the VDs and MDs, each of the switches can be drained or sourced with a corresponding voltage signal, e.g., Vᵢₙ, V_{SS}, Vₒᵤₜ.

The frontside interconnect structure is formed of a metal material. The metal material can be selected from the group consisting of aluminum, tungsten, tungsten nitride, copper, cobalt, silver, gold, chrome, ruthenium, platinum, titanium, titanium nitride, tantalum, tantalum nitride, nickel, hafnium, and combinations thereof. Other metal materials are within the scope of the present disclosure. The frontside interconnect structures can be formed by overlaying the frontside of the substrate with the above-listed metal material by, for example, chemical vapor deposition (CVD), physical vapor deposition (PVD), electroless plating, electroplating, or combinations thereof.

The method 2200 proceeds to operation 2216 in which a number of backside interconnect structures are formed, in accordance with various embodiments. Upon forming the back-end metal tracks, the substrate is flipped, and a number of backside interconnect structures (e.g., BM0 tracks, BM1 tracks) are formed over the backside of the substrate. For example, after the substrate is flipped, a polishing process may be performed on the backside of the substrate until a bottom surface of the epitaxial structures (e.g., the source/drain terminals formed in operation 2210) is exposed. Next, one or more dielectric layers are formed over the polished backside surface, followed by forming the above-described backside via structures (e.g., 314-320, 1418-1424, 1830-1844) that can each extend through the one or more dielectric layers to reach the bottom surface of a corresponding epitaxial structure. Next, the backside interconnect structures (e.g., 322-328, 330-332, 1426-1432, 1434-1436, 1850-1856, 1858-1864) can be formed in respective backside metallization layers.

In some embodiments, the backside interconnect structures in each of the backside metallization layers can have a first sub-group and a second sub-group, in which the first sub-group of backside interconnect structures are each coupled to the first common node (node X) and the second sub-group of backside interconnect structures are each coupled to the second common node (node Y). A first terminal of the fly capacitor (C_{F}) can be operatively formed by the first sub-group of backside interconnect structures (positive tracks), and a second terminal of the fly capacitor C_{F} can be operatively formed by the second sub-group of backside interconnect structures (negative tracks). Further, the first sub-group of backside interconnect structures and the second sub-group of backside interconnect structures may be alternately arranged with respect to one another, e.g., each of the first sub-group of backside interconnect structures is laterally adjacent to a corresponding one of the second sub-group of backside interconnect structures or laterally interposed between a corresponding pair of the second sub-group of backside interconnect structures. Consequently, within each backside metallization layer, a number of sub-capacitors of the fly capacitor C_{F} can be formed by the different sub-groups of backside interconnect structures. In addition, across different backside metallization layers, a number of additional sub-capacitors of the fly capacitor C_{F} can also be formed by the different sub-groups of backside interconnect structures.

The backside interconnect structure is formed of a metal material. The metal material can be selected from the group consisting of aluminum, tungsten, tungsten nitride, copper, cobalt, silver, gold, chrome, ruthenium, platinum, titanium, titanium nitride, tantalum, tantalum nitride, nickel, hafnium, and combinations thereof. Other metal materials are within the scope of the present disclosure. The backside interconnect structures can be formed by overlaying the backside of the substrate with the above-listed metal material by, for example, chemical vapor deposition (CVD), physical vapor deposition (PVD), electroless plating, electroplating, or combinations thereof.

In one aspect of the present disclosure, a semiconductor device is disclosed. The semiconductor device includes a first switch, a second switch, a third switch, and a fourth switch formed on a first side of a substrate, wherein the first switch and the second switch are connected in series between a first reference voltage and an output voltage, and wherein the third switch and the fourth switch are connected in series between the first reference voltage and a second reference voltage. The semiconductor device includes a capacitor formed on a second side of the substrate opposite to the first side, and having a first terminal and a second terminal. The first terminal is coupled to a first node between the first and second switches, and the second terminal is coupled to a second node between the third and fourth switches.

In another aspect of the present disclosure, a semiconductor device is disclosed. The semiconductor device includes a first transistor, a second transistor, a third transistor, and a fourth transistor formed on a first side of a substrate, wherein each of the first to fourth transistors having a first source/drain terminal and a second source/drain terminal. The semiconductor device includes a plurality of first metal tracks and a plurality of second metal tracks formed on a second side of the substrate opposite to the first side. Each of the first metal tracks has a first portion electrically coupled to the second source/drain terminal of the first transistor and to the first source/drain terminal of the second transistor. Each of the second metal tracks has a second portion electrically coupled to the second source/drain terminal of the third transistor and to the first source/drain terminal of the fourth transistor. Each of the first metal tracks is physically spaced from one or more adjacent ones of the second metal tracks.

In yet another aspect of the present disclosure, a method for fabricating semiconductor devices is disclosed. The method includes forming a first transistor, a second transistor, a third transistor, and a fourth transistor on a frontside of a substrate, wherein the first and second transistors are connected to each other with their first source/drain terminals at a first common node, and the third and fourth transistors are connected to each other with their first source/drain terminals at a second common node. The method includes forming a plurality of frontside metal tracks over the first to fourth transistors, wherein a first one of the frontside metal tracks is coupled to respective second source/drain terminals of the first and third transistors, and a second one of the frontside metal tracks is coupled to respective second source/drain terminals of the second and fourth transistors. The method includes forming a plurality of backside metal tracks on a back side of the substrate, wherein the plurality of backside metal tracks are spaced from one another with at least one dielectric, and wherein a first subset of the plurality of backside metal tracks are coupled to the first source/drain terminals of the first and second transistors, and a second subset of the plurality of backside metal tracks are coupled to the first source/drain terminals of the third and fourth transistors.

As used herein, the terms “about” and “approximately” generally indicates the value of a given quantity that can vary based on a particular technology node associated with the subject semiconductor device. Based on the particular technology node, the term “about” can indicate a value of a given quantity that varies within, for example, 10-30% of the value (e.g., +10%, ±20%, or ±30% of the value).

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

What is claimed is:

1. A semiconductor device, comprising:
a first switch, a second switch, a third switch, and a fourth switch formed on a first side of a substrate, wherein the first switch and the second switch are connected in series between a first reference voltage and an output voltage, and wherein the third switch and the fourth switch are connected in series between the first reference voltage and a second reference voltage; and
a capacitor formed on a second side of the substrate opposite to the first side, and having a first terminal and a second terminal;
wherein the first terminal is coupled to a first node between the first and second switches, and the second terminal is coupled to a second node between the third and fourth switches.

2. The semiconductor device of claim 1, wherein the first switch and the fourth switch are configured to be activated while the second switch and third switch are configured to be deactivated, causing voltages at the first terminal and at the second terminal to be equal to the first reference voltage and the second reference voltage, respectively.

3. The semiconductor device of claim 2, wherein, following the voltage at the first terminal being equal to the first reference voltage, the first switch and the fourth switch are configured to be deactivated while the second switch and third switch are configured to be activated, causing the voltages at the first terminal and at the second terminal to be equal to a multiple of the first reference voltage and the first reference voltage, respectively.

4. The semiconductor device of claim 1, further comprising:
a plurality of first metal tracks disposed in a first one of a plurality of metallization layers on the second side; and
a plurality of second metal tracks disposed in the first metallization layer.

5. The semiconductor device of claim 4, wherein the plurality of first metal tracks collectively serve as the first terminal of the capacitor, and the plurality of second metal tracks collectively serve as the second terminal of the capacitor.

6. The semiconductor device of claim 4, wherein the plurality of first metal tracks and the plurality of second metal tracks are alternately arranged with each other along a first lateral direction.

7. The semiconductor device of claim 4, further comprising:
a plurality of first via structures coupling the first node to the plurality of first metal tracks, respectively; and
a plurality of second via structures coupling the second node to the plurality of second metal tracks.

8. The semiconductor device of claim 4, further comprising:
a plurality of third metal tracks disposed in a second one of a plurality of metallization layers on the second side; and
a plurality of fourth metal tracks disposed in the second metallization layer.

9. The semiconductor device of claim 8, wherein the plurality of third metal tracks collectively serve as the first terminal of the capacitor, and the plurality of fourth metal tracks collectively serve as the second terminal of the capacitor.

10. The semiconductor device of claim 4, wherein the plurality of first metal tracks and the plurality of second metal tracks are disposed directly below the first to fourth switches.

11. The semiconductor device of claim 1, wherein each of the first to fourth switches includes a transistor having a source terminal and a drain terminal, with either the source or drain terminal coupled to one of the first or second terminal of the capacitor.

12. A semiconductor device, comprising:
a first transistor, a second transistor, a third transistor, and a fourth transistor formed on a first side of a substrate, wherein each of the first to fourth transistors having a first source/drain terminal and a second source/drain terminal; and
a plurality of first metal tracks and a plurality of second metal tracks formed on a second side of the substrate opposite to the first side;
wherein each of the first metal tracks has a first portion electrically coupled to the second source/drain terminal of the first transistor and to the first source/drain terminal of the second transistor;
wherein each of the second metal tracks has a second portion electrically coupled to the second source/drain terminal of the third transistor and to the first source/drain terminal of the fourth transistor; and
wherein each of the first metal tracks is physically spaced from one or more adjacent ones of the second metal tracks.

13. The semiconductor device of claim 12, wherein each of the first metal tracks is physically spaced from the one or more adjacent second metal tracks with an inter-metal dielectric (IMD) interposed therebetween.

14. The semiconductor device of claim 12, wherein each of the first metal tracks is physically spaced from the one or more adjacent second metal tracks with an inter-metal dielectric (IMD) and a high-k dielectric interposed therebetween.

15. The semiconductor device of claim 12, wherein the first metal tracks collectively serve as a first terminal of a capacitor, and the second metal tracks collectively serve as a second terminal of the capacitor.

16. The semiconductor device of claim 15, wherein the first transistor and the fourth transistor are configured to be activated while the second transistor and third transistor are configured to be deactivated, causing voltages at the first terminal and at the second terminal of the capacitor to be equal to a first reference voltage and a second reference voltage, respectively.

17. The semiconductor device of claim 16, wherein, following the voltage at the first terminal being equal to the first reference voltage, the first transistor and the fourth transistor are configured to be deactivated while the second transistor and third transistor are configured to be activated, causing the voltages at the first terminal and at the second terminal to be equal to a multiple of the first reference voltage and the first reference voltage, respectively.

18. The semiconductor device of claim 12, wherein the respective first portions of the first metal tracks are aligned with one another along a lateral direction perpendicular to a lengthwise direction of the first and second metal tracks, and wherein the respective second portions of the second metal tracks are also aligned with one another along the lateral direction.

19. A method for fabricating semiconductor devices, comprising:
forming a first transistor, a second transistor, a third transistor, and a fourth transistor on a frontside of a substrate, wherein the first and second transistors are connected to each other with their first source/drain terminals at a first common node, and the third and fourth transistors are connected to each other with their first source/drain terminals at a second common node;
forming a plurality of frontside metal tracks over the first to fourth transistors, wherein a first one of the frontside metal tracks is coupled to respective second source/drain terminals of the first and third transistors, and a second one of the frontside metal tracks is coupled to respective second source/drain terminals of the second and fourth transistors; and
forming a plurality of backside metal tracks on a back side of the substrate, wherein the plurality of backside metal tracks are spaced from one another with at least one dielectric, and wherein a first subset of the plurality of backside metal tracks are coupled to the first source/drain terminals of the first and second transistors, and a second subset of the plurality of backside metal tracks are coupled to the first source/drain terminals of the third and fourth transistors.

20. The method of claim 19, wherein the first subset of the backside metal tracks operatively serve as a first terminal of a capacitor, and the second subset of the backside metal tracks operatively serve as a second terminal of the capacitor.
